(19) United States
(12) Patent Application Publication
(10) Pub. No.: US 2025/0226299 A1
(43) Pub. Date: Jul. 10, 2025

(54) SEMICONDUCTOR PACKAGE AND METHOD FOR FABRICATING THE SAME

(71) Applicant: SAMSUNG ELECTRONICS CO., LTD., SUWON-SI (KR)

(72) Inventors: TAE OH HA, Suwon-si (KR); JUSUK KANG, Suwon-si (KR); JONGHO PARK, Suwon-si (KR); CHANWOOK PARK, Suwon-si (KR); JAEMOK JUNG, Suwon-si (KR); JU-IL CHOI, Suwon-si (KR)

(21) Appl. No.: 18/885,964

(22) Filed: Sep. 16, 2024

(30) Foreign Application Priority Data
Jan. 8, 2024 (KR) 10-2024-0003040
Mar. 22, 2024 (KR) 10-2024-0040046

(51) Int. Cl. H01L 23/498; H01L 21/48; H01L 23/00; H01L 23/31

(52) U.S. Cl. CPC H01L 23/49811; H01L 21/4853; H01L 21/4857; H01L 23/3107; H01L 23/49822; H01L 23/49866; H01L 24/13; H01L 24/20; H01L 24/32; H01L 24/73; H01L 2224/16227; H01L 2224/214; H01L 2224/32225; H01L 2224/73204; H01L 2224/73259; H01L 2224/73267

(57) ABSTRACT

A semiconductor package includes a lower package substrate including a lower redistribution insulation layer and a lower redistribution pattern; a semiconductor chip disposed on the lower package substrate; a molding member disposed on the lower package substrate and covering at least a portion of the semiconductor chip; a conductive post disposed in the molding member; and a lower redistribution pad disposed between the conductive post and the lower redistribution pattern, wherein the lower redistribution pad includes a pad hole extending from an upper surface of the lower redistribution pad toward a lower surface of the lower redistribution pad, and a portion of the conductive post is disposed in the pad hole.

### CROSS-REFERENCE TO RELATED APPLICATIONS

This application claims priority to and the benefit of Korean Patent Application No. 10-2024-0003040 filed in the Korean Intellectual Property Office on Jan. 8, 2024, and Korean Patent Application No. 10-2024-0040046 filed in the Korean Intellectual Property Office on Mar. 22, 2024, the entire contents of which are herein incorporated by reference.

### BACKGROUND

### 1. Technical Field

The present disclosure relates to a semiconductor package and a method for fabricating the same, and more particularly to a semiconductor package including a lower redistribution pad for a having a pad hole.

### 2. Discussion of Related Art

There is an increasing demand for a high-capacity, thin, and miniaturized semiconductor devices and electronic products using the same. These demands have led to various emerging package technologies in the semiconductor industry. For example, package-on-package (POP) technology is being developed in the semiconductor packaging field.

In the package-on-package technology, two or more semiconductor packages may be stacked, which may lead to cracks or separation defects occurring in a conductive structure disposed between the two or more semiconductor packages.

### SUMMARY

The present disclosure attempts to provide a semiconductor package having improved reliability and a method for fabricating the same.

According to an embodiment, provided is a semiconductor package including: a lower package substrate including a lower redistribution insulation layer and a lower redistribution pattern; a semiconductor chip disposed on the lower package substrate; a molding member disposed on the lower package substrate and covering at least a portion of the semiconductor chip; a conductive post disposed in the molding member; and a lower redistribution pad disposed between the conductive post and the lower redistribution pattern, wherein the lower redistribution pad includes a pad hole extending from an upper surface of the lower redistribution pad toward a lower surface of the lower redistribution pad, and a portion of the conductive post is disposed in the pad hole.

According to an embodiment, provided is a semiconductor package including: a lower package substrate including a lower redistribution insulation layer and a lower redistribution pattern; a semiconductor chip mounted on the lower package substrate; a connection terminal disposed between the lower package substrate and the semiconductor chip; a molding member disposed on the lower package substrate and covering at least a portion of the semiconductor chip; a conductive post disposed in the molding member; a first lower redistribution pad disposed between the lower redistribution pattern and the connection terminal; a second lower redistribution pad disposed at substantially the same level as the first lower redistribution pad, between the conductive post and the lower redistribution pattern; and an upper package substrate disposed on the molding member, and including an upper redistribution insulation layer and an upper redistribution pattern connected to the conductive post, wherein the second lower redistribution pad includes a pad hole extending from an upper surface of the second lower redistribution pad toward a lower surface of the second lower redistribution pad, and the conductive post includes a first part disposed in the pad hole and a second part disposed on the first part and covering at least a portion of the upper surface of the second lower redistribution pad, a width of the first part and a width of the second part of the conductive post are different from each other.

According to an embodiment, provided is a method for fabricating a semiconductor package, the method including: forming a lower package substrate including a lower redistribution insulation layer and a lower redistribution pattern; forming a pad seed material layer on the lower package substrate; forming a preliminary lower redistribution pad disposed on the pad seed material layer, and including a pad hole exposing the pad seed material layer; forming a conductive post on the pad seed material layer exposed through the pad hole and on at least a portion of the preliminary lower redistribution pad; forming a lower redistribution pad by removing a portion of the pad seed material layer; mounting a semiconductor chip on the lower package substrate and spaced apart from the conductive post; and forming a molding member covering the conductive post and the semiconductor chip.

As set forth herein and according to some embodiments, a pad hole may be formed in a lower redistribution pad connected to a conductive post, and the pad hole may improve the bonding strength between the conductive post and the lower redistribution pad, and may simultaneously enable the omission of a separate seed metal layer to form the conductive post. According to some embodiments, a semiconductor package may be produced with improved reliability, and a method of manufacturing a semiconductor package may have a high productivity.

### BRIEF DESCRIPTION OF THE DRAWINGS

FIG. 1 is a cross-sectional view of a semiconductor package according to an embodiment.

FIG. 2 is a plan view showing a lower redistribution pad and a conductive post, included in the semiconductor package of FIG. 1.

FIG. 3 is an enlarged view of region R1 of FIG. 1.

FIGS. 4 through 15 are cross-sectional views sequentially showing a method for fabricating a semiconductor package according to an embodiment.

### DETAILED DESCRIPTION

Hereinafter, embodiments of the present disclosure are described in detail with reference to the accompanying drawings. The present disclosure may be implemented in various different forms and is not limited to embodiments provided herein. Embodiments may be modified in various different ways, all without departing from the spirit or scope of the present disclosure. In order to clearly describe aspects of the present disclosure, parts or portions that may be irrelevant to the description may be omitted.

Components or steps unrelated to aspects of the description may be omitted in order to clearly describe the present disclosure. The same or similar components are denoted by the same reference numeral in the drawings and throughout the specification.

In addition, the size and thickness of each component shown in the accompanying drawings may be arbitrarily shown for convenience of explanation, and the present disclosure is not limited thereto. The thicknesses of layers and/or regions may be exaggerated in the drawings for convenience of explanation and in order to clearly represent these layers and regions.

It will be understood that when an element such as a layer, a film, a region or a board is referred to as being “on” or “above” another element, the element may be “directly on” another element or may have a third element interposed therebetween. On the other hand, when an element is referred to as being “directly on” another element, there is no third element interposed therebetween. In addition, when an element is referred to as being “on” or “above” a reference element, the element may be disposed on or below the reference element, and may not necessarily be “on” or “above” the reference element in an opposite direction of gravity.

Unless explicitly described to the contrary, the words “include” or “comprise”, and variations such as “including”, “comprises” or “comprising”, will be understood to imply the inclusion of stated elements but not the exclusion of any other elements.

In addition, throughout the specification, the phrase “on a plane” may indicate a case where an object is viewed from the top, and an expression “on a cross-section” may indicate a case where a cross-section of the object taken along a vertical direction is viewed from its side.

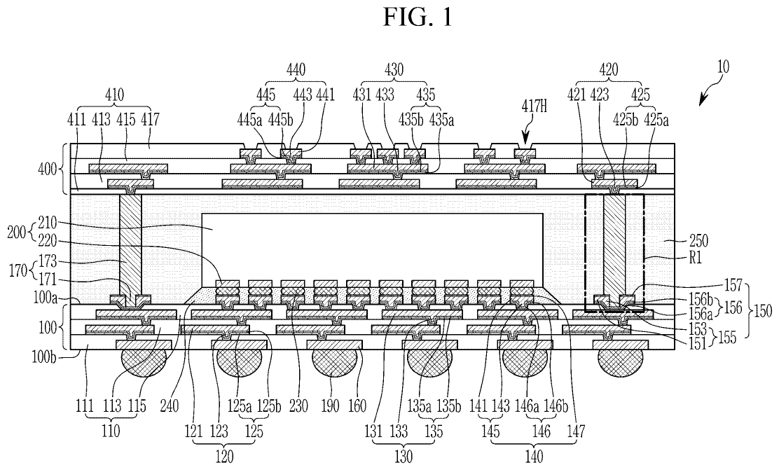

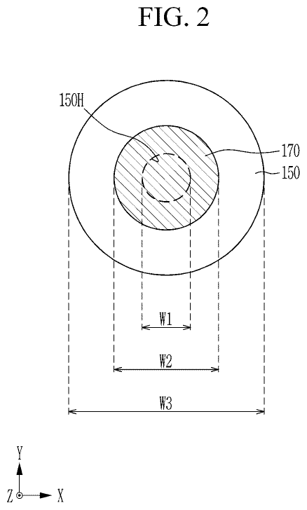

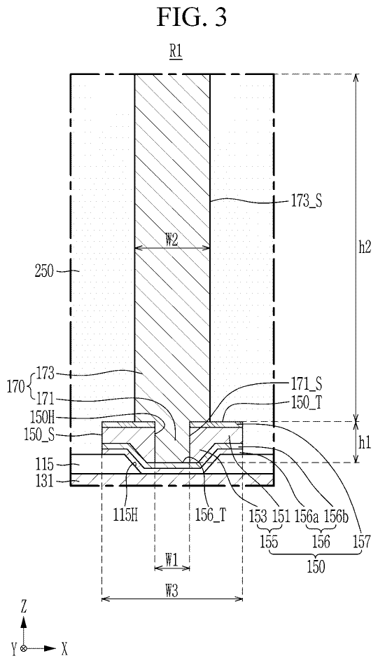

Hereinafter, a semiconductor package is described according to an embodiment with reference to FIG. 1, FIG. 2, and FIG. 3.

FIG. 1 is a cross-sectional view of a semiconductor package according to an embodiment. FIG. 2 is a plan view showing a lower redistribution pad and a conductive post, included in the semiconductor package of FIG. 1. FIG. 3 is an enlarged view of region R1 of the semiconductor package of FIG. 1.

Referring to FIG. 1, FIG. 2, and FIG. 3, a semiconductor package 10 according to an embodiment may include a lower package substrate 100, a conductive post 170, an external connection terminal 190, a lower semiconductor chip 200, a chip connection terminal 230, an underfill member 240, a molding member 250, and an upper package substrate 400.

In an embodiment, the lower package substrate 100 may be a redistribution substrate. However, the lower package substrate 100 is not limited thereto. In some embodiments, the lower package substrate 100 may be a printed circuit board (PCB), a ceramic substrate, a substrate for a wafer level package (WLP), or a substrate for a package level package (PLP). Hereinafter, and for purposes of the description, the lower package substrate 100 may be assumed to be the redistribution substrate.

The lower package substrate 100 may include a lower redistribution insulation layer 110, a plurality of lower redistribution patterns 120 and 130, a plurality of lower redistribution pads 140 and 150, and an external electrode pad 160.

The lower package substrate 100 may have a first surface 100a and a second surface 100b opposite to each other. In the disclosure, a first direction X may refer to a direction parallel to the first surface 100a of the lower package substrate 100, a second direction Y may refer to a direction parallel to the first surface 100a of the lower package substrate 100 and perpendicular to the first direction X, and a third direction Z may refer to a direction perpendicular to the first surface 100a of the lower package substrate 100.

The lower redistribution insulation layer 110 may include a plurality of lower redistribution insulation layers 111, 113, and 115. The plurality of lower redistribution insulation layers 111, 113, and 115 of the lower redistribution insulation layer 110 may include a first lower redistribution insulation layer 111, a second lower redistribution insulation layer 113, and a third lower redistribution insulation layer 115. The plurality of lower redistribution insulation layers 111, 113, and 115 may be sequentially stacked.

FIG. 1 shows that the lower redistribution insulation layer 110 includes three insulation layers. However, the number of insulation layers included in the lower redistribution insulation layer 110 is not limited thereto, and the number of insulation layers may be changed. For example, the lower redistribution insulation layer 110 may omit one or more of the first to the third lower redistribution insulation layers 111, 113, and 115, or may further include one or more additional insulation layers in addition to the first to the third lower redistribution insulation layers 111, 113, and 115. As another example, the insulation layer included in the lower package substrate 100 may be one insulation layer.

Each of the first to the third lower redistribution insulation layers 111, 113, and 115 may include, for example, an organic compound.

In some embodiments, each of the first to the third lower redistribution insulation layers 111, 113, and 115 may include a photo imageable dielectric (PID) insulating material, which may undergo a photoresist process. For example, each of the first to third lower redistribution insulation layers 111, 113, and 115 may include photosensitive polyimide (PSPI).

In some embodiments, each of the first to third lower redistribution insulation layers 111, 113, and 115 may include oxide or nitride. For example, each of the first to third lower redistribution insulation layers 111, 113, and 115 may include silicon oxide or silicon nitride.

The lower package substrate 100 may include a first lower redistribution pattern 120, a second lower redistribution pattern 130, a first lower redistribution pad 140, and a second lower redistribution pad 150. The first lower redistribution pattern 120, the second lower redistribution pattern 130, the first lower redistribution pad 140 may be sequentially disposed in the lower redistribution insulation layer 110. The first lower redistribution pad 140 and the second lower redistribution pad 150 may be disposed at the same level in the lower package substrate 100.

FIG. 1 shows the lower package substrate 100 including the first and second lower redistribution patterns 120 and 130. However, the number of lower redistribution patterns included in the lower package substrate 100 is not limited thereto, and the number of lower redistribution patterns may be changed. For example, the lower package substrate 100 may omit one of the first and second lower redistribution patterns 120 and 130, or may include one or more additional redistribution patterns.

The first lower redistribution pattern 120 may include a first lower conductive line pattern 121 and a first lower conductive via pattern 123, which may be integrated with each other. The second lower redistribution pattern 130 may include a second lower conductive line pattern 131 and a second lower conductive via pattern 133, which may be integrated with each other.

The first lower conductive line pattern 121 may be disposed on at least one of the upper and lower surfaces of each of the first and second lower redistribution insulation layers 111 and 113. The second lower conductive line pattern 131 may be disposed on at least one of the upper and lower surfaces of each of the first and second lower redistribution insulation layers 111 and 113.

The first lower conductive via pattern 123 may pass through at least a portion of the first lower redistribution insulation layer 111, and the second lower conductive via pattern 133 may pass through at least a portion of the second lower redistribution insulation layer 113. The first and second lower conductive via patterns 123 and 133 may be connected to the first and second lower conductive line patterns 121 and 131, respectively. The first lower conductive via pattern 123 and the first lower conductive line pattern 121 may be disposed on the external electrode pad 160. The lower redistribution pads 140 and 150 may be disposed on the second lower conductive via pattern 133 and the second lower conductive line pattern 131.

A width of the first lower conductive line pattern 121 in the first direction X may be greater than a width of the first lower conductive via pattern 123 in the first direction X. A width of the second lower conductive line pattern 131 in the first direction X may be greater than a width of the second lower conductive via pattern 133 in the first direction X. One or more of the first or second lower conductive via pattern 123 or 133 may have a width in the first direction X that is gradually smaller in a direction from the first surface 100a of the lower package substrate 100 to the second surface 100b of the lower package substrate 100. Here, one or more of the first or second lower conductive via pattern 123 or 133 may have a tapered width in the first direction X that is gradually smaller in the direction from the first surface 100a of the lower package substrate 100 to the second surface 100b of the lower package substrate 100.

One or more lower redistribution pattern of the plurality of lower redistribution patterns 120 or 130, which may include the first or second lower conductive line pattern 121 or 131 and the first or second lower conductive via pattern 123 or 133, may have a ‘T’ shaped cross section.

The first lower conductive line pattern 121 may be disposed directly on the first lower conductive via pattern 123. The second lower conductive line pattern 131 may be disposed directly on the second lower conductive via pattern 133. For example, a boundary surface may be omitted from between at least one of the first lower conductive line pattern 121 and the first lower conductive via pattern 123 or the second lower conductive line pattern 131 and the second lower conductive via pattern 133. However, a relationship between the first and second lower conductive line pattern 121 and 131 and the first and second lower conductive via pattern 123 and 133, and a shape of the first and second lower redistribution patterns 120 or 130 are not limited thereto, and may be changed in various ways.

In detail, the first lower conductive line pattern 121 of the first lower redistribution pattern 120 may be disposed on the upper surface of the first lower redistribution insulation layer 111. An upper surface of the first lower conductive line pattern 121 may be covered by the second lower redistribution insulation layer 113.

The first lower conductive via pattern 123 of the first lower redistribution pattern 120 may extend in a vertical direction by passing through at least a portion of the first lower redistribution insulation layer 11, and may be connected between the first lower conductive line pattern 121 and the external electrode pad 160. That is, the first lower conductive via pattern 123 may be disposed in an opening of the first lower redistribution insulation layer 111 that exposes at least a portion of an upper surface of the external electrode pad 160.

The second lower conductive line pattern 131 of the second lower redistribution pattern 130 may be disposed on the upper surface of the second lower redistribution insulation layer 113. An upper surface of the second lower conductive line pattern 131 may be covered by the third lower redistribution insulation layer 115.

The second lower conductive via pattern 133 of the second lower redistribution pattern 130 may extend in the vertical direction by passing through at least a portion of the second lower redistribution insulation layer 113, and may be connected between the first lower conductive line pattern 121 and the second lower conductive line pattern 131. That is, the second lower conductive via pattern 133 may be disposed in an opening of the second lower redistribution insulation layer 113 that exposes at least a portion of the upper surface of the first lower conductive line pattern 121.

Each of the first and second lower redistribution patterns 120 and 130 may include a conductive material. For example, the first and second lower redistribution pattern 120 and 130 may each include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof. However, a material included in the first or second lower redistribution pattern 120 or 130 may not be limited thereto, and may be changed in various ways.

The first lower redistribution pattern 120 may include a first lower redistribution seed pattern 125 disposed between the first lower redistribution insulation layer 111 and the first lower conductive line pattern 121, or between the first lower redistribution insulation layer 111 or 113 and the first or second lower conductive via pattern 123. The second lower redistribution pattern 130 may include a second lower redistribution seed pattern 135 disposed between the second lower redistribution insulation layer 113 and the second lower conductive line pattern 131, or between the second lower redistribution insulation layer 113 and the second lower conductive via pattern 133.

The first lower redistribution seed pattern 125 may conformally extend along an inner surface of the opening of the first lower redistribution insulation layer 111. That is, the first lower redistribution seed pattern 125 may conformally extend along the lower surface of the first lower conductive line pattern 121 and the lower and side surface of the first lower conductive via pattern 123. The second lower redistribution seed pattern 135 may conformally extend along an inner surface of the opening of the second lower redistribution insulation layer 113. That is, the second lower redistribution seed pattern 135 may conformally extend along the lower surface of the second lower conductive line pattern 131 and the lower and side surface of the second lower conductive via pattern 133.

A thickness of the first lower redistribution seed pattern 125 may be less than a thickness of the first lower conductive line pattern 121 and a thickness of the first lower conductive via pattern 123. A thickness of the second lower redistribution seed pattern 135 may be smaller than a thickness of the second lower conductive line pattern 131 and a thickness of the second lower conductive via pattern 133.

In an embodiment, at least one of the first or second lower redistribution seed patterns 125 or 135 may include a multi-layer structure. For example, the first lower redistribution seed pattern 125 may include a first lower redistribution seed layer 125a and a second lower redistribution seed layer 125b, and the second lower redistribution seed pattern 135 may include a first lower redistribution seed layer 135a and a second lower redistribution seed layer 135b.

The first lower redistribution seed layers 125a and 135a may be disposed between the first and second lower redistribution insulation layers 111 and 113 and the second lower redistribution seed layers 125b and 135b, respectively, and the second lower redistribution seed layers 125b or 135b may be disposed between the first and second lower redistribution patterns 120 and 130 and the first lower redistribution seed layers 125a and 135a, respectively.

The first and second lower redistribution seed patterns 125 and 135 may each include a conductive material. For example, the first and second lower redistribution seed patterns 125 and 135 may each include at least one of copper (Cu), titanium (Ti), titanium tungsten (TiW), titanium nitride (TiN), tantalum (Ta), tantalum nitride (TaN), chromium (Cr), or aluminum (Al), or a combination thereof.

In an embodiment, the first lower redistribution seed layers 125a and 135a may include a material different from the second lower redistribution seed layers 125b and 135b. For example, the first lower redistribution seed layers 125a and 135a may include titanium (Ti) or titanium tungsten (TiW), and the second lower redistribution seed layers 125b and 135b may include copper (Cu). Accordingly, one or more of the first or second lower redistribution seed patterns 125 or 135 may have a Cu/Ti structure in which copper (Cu) is stacked on titanium (Ti) or a Cu/TiW structure in which copper (Cu) is stacked on titanium tungsten (TiW).

In some embodiments, one or more of the first or second lower redistribution patterns 120 or 130 may include copper (Cu). In this case, at least a portion of at least one of the first or second lower redistribution seed patterns 125 or 135 may serve as a diffusion barrier layer.

The lower package substrate 100 may include the first lower redistribution pad 140 and the second lower redistribution pad 150, disposed on the first surface 100a.

The first and the second lower redistribution pads 140 and 150 may be disposed on the third lower redistribution insulation layer 115 of the lower package substrate 100. That is, the first and the second lower redistribution pads 140 and 150 may be disposed at substantially the same level.

The first lower redistribution pad 140 may be disposed below the lower semiconductor chip 200. The first lower redistribution pad 140 may serve as a pad connecting the lower semiconductor chip 200 and the lower package substrate 100 to each other. The second lower redistribution pad 150 may be disposed outside a width of the lower semiconductor chip 200 and below the conductive post 170. The second lower redistribution pad 150 may serve as a pad connecting the conductive post 170 and the lower package substrate 100 to each other.

The first lower redistribution pad 140 may include a first pad conductive pattern 145, a first pad seed pattern 146, and a first pad capping pattern 147. In detail, the first pad conductive pattern 145 may include a first pad line pattern 141 and a first pad via pattern 143 integrated with each other.

The second lower redistribution pad 150 may include a second pad conductive pattern 155, a second pad seed pattern 156, and a second pad capping pattern 157. In detail, the second pad conductive pattern 155 may include a second pad line pattern 151 and a second pad via pattern 153 integrated with each other.

The first and second pad line pattern 141 and 151 may be disposed on an upper surface of the third lower redistribution insulation layer 115. That is, the first and second pad line pattern 141 and 151 may protrude above the first surface 100a of the lower package substrate 100.

The first and second pad via pattern 143 and 153 may extend in the vertical direction by passing through the third lower redistribution insulation layer 115, and may be connected to the second lower redistribution pattern 130. That is, the first and second pad via pattern 143 and 153 may be disposed in respective openings of the third lower redistribution insulation layer 115 that each expose a portion of the upper surface of the second lower conductive line pattern 131 of the second lower redistribution pattern 130.

Accordingly, the first and second lower redistribution pads 140 and 150 may be connected to at least one of the first lower redistribution pattern 120 and the external electrode pad 160 by the second lower redistribution pattern 130.

A width of the first pad line pattern 141 in the first direction X may be greater than a width of the first pad via pattern 143 in the first direction X. The first pad via pattern 143 may have the width in the first direction X that is gradually smaller in the direction from the first surface 100a of the lower package substrate 100 to the second surface 100b of the lower package substrate 100. Here, the first pad via pattern 143 may have a tapered width in the first direction X that is gradually smaller in the direction from the first surface 100a of the lower package substrate 100 to the second surface 100b of the lower package substrate 100.

A width of the second pad line pattern 151 in the first direction X may be greater than a width of the second pad via pattern 153 in the first direction X. The second pad via pattern 153 may have the width in the first direction X that is gradually smaller in the direction from the first surface 100a of the lower package substrate 100 to the second surface 100b of the lower package substrate 100. Here, the second pad via pattern 153 may have a tapered width in the first direction X that is gradually smaller in the direction from the first surface 100a of the lower package substrate 100 to the second surface 100b of the lower package substrate 100.

The first lower redistribution pad 140, including the first pad line pattern 141 and the first pad via pattern 143, may have the “T” shaped cross section. The second pad conductive pattern 155 and the second pad capping pattern 157 of the second lower redistribution pad 150 may have donut-shaped shaped cross section. The second pad conductive pattern 155, the second pad seed pattern 156, and the second pad capping pattern 157 of the second lower redistribution pad 150 may form a bowl-shaped pattern in which at least a portion of the second pad seed pattern 156 may be exposed at a center portion of the second lower redistribution pad 150.

The first pad line pattern 141 may be disposed directly on the first pad via pattern 143. The second pad line pattern 151 may be disposed directly on the second pad via pattern 153. For example, a boundary surface may be omitted from between at least one of the first pad line pattern 141 and the first pad via pattern 143 or the second pad line pattern 151 and the second pad via pattern 153. However, a relationship between the first and second pad line pattern 141 and 151 and the first and second pad via pattern 143 and 153, and a cross sectional shape of the first and second lower redistribution pads 140 and 150 are not limited thereto, and may be changed in various ways.

Each of the first and second pad conductive patterns 145 and 155 may include a conductive material. For example, the first and second pad conductive pattern 145 and 155 may each include copper (Cu) or a copper alloy.

The first or second pad seed pattern 146 or 156 may be disposed between the third lower redistribution insulation layer 115 and the first or second pad conductive pattern 145 or 155.

The first and second pad seed pattern 146 and 156 may conformally extend along an inner surface of the opening of the third lower redistribution insulation layer 115. That is, the first pad seed pattern 146 may conformally extend along a lower surface of the first pad line pattern 141 and the lower surface and side surface of the first pad via pattern 143, and the second pad seed pattern 156 may conformally extend along a lower surface of the second pad line pattern 151 and the lower surface and side surface of the second pad via pattern 153.

A thickness of the first pad seed pattern 146 may be smaller than a thickness of the first pad line pattern 141 and a thickness of the first pad via pattern 143. A thickness of the second pad seed pattern 156 may be smaller than a thickness of the second pad line pattern 151 and a thickness of the second pad via pattern 153.

In an embodiment, at least one of the first or second pad seed patterns 146 or 156 may include a multi-layer structure. For example, the first pad seed pattern 146 may include a first pad seed layer 146a and a second pad seed layer 146b sequentially stacked between the third lower redistribution insulation layer 115 and the first pad conductive pattern 145, and the second pad seed pattern 156 may include a first pad seed layer 156a and a second pad seed layer 156b sequentially stacked between the third lower redistribution insulation layer 115 and the second pad conductive pattern 155.

The first pad seed layers 146a and 156a may be disposed between the third lower redistribution insulation layer 115 and the second pad seed layer 146b and 156b, respectively, and the second pad seed layers 146b and 156b may be disposed between the first pad seed layer 146a and 156a and the first and second pad conductive patterns 145 and 155, respectively.

The first and second pad seed patterns 146 and 156 may each include a conductive material. For example, the first and second pad seed patterns 146 and 156 may include at least one of copper (Cu), titanium (Ti), titanium tungsten (TiW), titanium nitride (TiN), tantalum (Ta), tantalum nitride (TaN), chromium (Cr), or aluminum (Al), or a combination thereof.

In an embodiment, the first pad seed layers 146a and 156a may include a material different from the first pad seed layers 146b and 156b. For example, the first pad seed layer 146a or 156a may include titanium (Ti) or titanium tungsten (TiW), and the first pad seed layers 146b and 156b may include copper (Cu). Accordingly, one or more of the first or second pad seed pattern 146 or 156 may have the Cu/Ti structure in which copper (Cu) is stacked on titanium (Ti) or the Cu/TiW structure in which copper (Cu) is stacked on titanium tungsten (TiW).

The first and second pad capping patterns 147 and 157 may be disposed on the first and second pad conductive patterns 145 and 155, respectively. The first and second pad capping patterns 147 and 157 may cover an upper surface of the first and second pad conductive pattern 145 and 155, respectively.

The first and second pad capping patterns 147 and 157 may serve as a protection layer for protecting the first and second pad conductive patterns 145 and 155, respectively. The first and second pad capping patterns 147 and 157 serve as a bonding layer for bonding the first and second pad conductive patterns 145 and 155 and another component to each other, respectively.

In an embodiment, the first or second pad capping pattern 147 or 157 may include a conductive material different from that of the first or second pad conductive pattern 145 or 155, or the first or second pad seed pattern 146 or 156. For example, one or more of the first or second pad capping pattern 147 or 157 may include at least one of nickel (Ni), or gold (Au), or an alloy thereof. However, this configuration is an example, and the material(s) included in the first or second pad capping pattern 147 or 157 may be changed in various ways.

The second lower redistribution pad 150 may include a pad hole 150H passing through at least a portion of the second lower redistribution pad 150.

In detail, the pad hole 150H of the second lower redistribution pad 150 may extend from an upper surface of the second lower redistribution pad 150 to its lower surface in the third direction Z, which is a vertical direction. The pad hole 150H may be disposed in a center portion of the second lower redistribution pad 150. However, a location of the pad hole 150H is not limited thereto, and may be changed in various ways.

The pad hole 150H of the second lower redistribution pad 150 may pass through the second pad conductive pattern 155 and second pad capping pattern 157 of the second lower redistribution pad 150. The pad hole 150H may expose a portion of an upper surface 156_T of the second pad seed pattern 156.

The pad hole 150H of the second lower redistribution pad 150 may pass through the second pad line pattern 151 and second pad via pattern 153 of the second pad conductive pattern 155, and may overlap an opening 115H of the third lower redistribution insulation layer 115 in the third direction Z, which is the vertical direction.

At least a portion of the conductive post 170 described herein may be disposed in the pad hole 150H of the second lower redistribution pad 150. A description of the conductive post 170 is provided herein in detail.

The external electrode pad 160 may be disposed at the second surface 100b of the lower package substrate 100. The external electrode pad 160 may be in contact with the second surface 100b of the lower package substrate 100. The external electrode pad 160 may be embedded in a direction from the second surface 100b of the lower package substrate 100 to the first surface 100a. For example, at least a portion of external electrode pad 160 may be embedded in a direction from the second surface 100b of the lower package substrate 100 to the first surface 100a.

The external electrode pad 160 may be embedded in the first lower redistribution insulation layer 111 of the lower package substrate 100. For example, a lower surface of the external electrode pad 160 may be coplanar with the second surface 100b of the lower package substrate 100. The upper surface of the external electrode pad 160 may be covered by the first lower redistribution insulation layer 111. However, a location of the external electrode pad 160 is not limited thereto, and may be changed in various ways. For example, the external electrode pad 160 may be disposed on the second surface 100b of the lower package substrate 100.

The external electrode pad 160 may include a conductive material. For example, the external electrode pad 160 may include any one of the metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof. However, a material included in the external electrode pad 160 is not limited thereto, and may be changed.

The external connection terminal 190 may be disposed on the external electrode pad 160. For example, the external connection terminal 190 may be disposed directly on the external electrode pad 160. The external connection terminal 190 may protrude from the second surface 100b of the lower package substrate 100, and may be connected to the external electrode pad 160.

The external connection terminal 190 may be, for example, at least one of a solder ball, a pillar, or a bump. The external connection terminal 190 may have a width the first direction X that is less than or equal to a width of the external electrode pad 160. However, a type and size of the external connection terminal 190 is not limited thereto, and may be changed in various ways.

The external connection terminal 190 may include a conductive material. For example, the external connection terminal 190 may include any one of a metal such as tin (Sn), silver (Ag), zinc (Zn), or a lead (Pb), or an alloy thereof. However, the conductive material included in the external connection terminal 190 is not limited thereto, and may be changed.

The semiconductor package 10 according to an embodiment may be electrically connected and mounted on a module substrate or system substrate of an electronic product through the external connection terminal 190. The external electrode pad 160 may serve as an under bump metallurgy (UBM) where the external connection terminal 190 is disposed.

The semiconductor package 10 may omit the external connection terminal 190. For example, the external connection terminal 190 may be provided by the module substrate or system substrate of an electronic product on which the semiconductor package 10 may be mounted.

The lower semiconductor chip 200 may be mounted on the first surface 100a of the lower package substrate 100. For example, the lower semiconductor chip 200 may be mounted on the lower package substrate 100 by using a flip chip method.

The lower semiconductor chip 200 may be a memory chip or a logic chip. For example, the memory chip may be a volatile memory chip such as a dynamic random access memory (DRAM) or a static random access memory (SRAM), or a non-volatile memory chip such as a phase-change random access memory (PRAM), a magnetoresistive random access memory (MRAM), a ferroelectric random access memory (FeRAM), or a resistive random access memory (RRAM).

In some embodiments, the memory chip may be a high bandwidth memory (HBM) DRAM semiconductor chip. In addition, the logic chip may be a microprocessor, an analog element, or a digital signal processor.

The lower semiconductor chip 200 may include a semiconductor substrate 210 and a plurality of chip pads 220. The plurality of chip pads 220 may be disposed on a surface of the semiconductor substrate 210. The plurality of chip pads 220 may be disposed on a surface of the semiconductor substrate 210 and face the first surface 100a of the lower package substrate 100. That is, the plurality of chip pads 220 may face the first lower redistribution pad 140 disposed on the first surface 100a of the lower package substrate 100.

The semiconductor substrate 210 may include silicon (Si), for example. Alternatively, the semiconductor substrate 210 may include a semiconductor element such as germanium (Ge), or a compound semiconductor such as silicon carbide (SiC), gallium arsenide (GaAs), indium arsenide (InAs), or indium phosphide (InP). However, a material included in the semiconductor substrate 210 is not limited thereto, and may be changed.

The semiconductor substrate 210 may have an active surface and an inactive surface opposite to the active surface. For example, the semiconductor substrate 210 may be mounted with the active surface facing the first surface 100a of the lower package substrate 100.

The lower semiconductor chip 200 may have a semiconductor device including one or more types of individual devices and may be disposed on the active surface of the semiconductor substrate 210.

The chip connection terminal 230 may be disposed between the chip pad 220 of the lower semiconductor chip 200 and the first lower redistribution pad 140. The chip connection terminal 230 may electrically connect the chip pad 220 of the lower semiconductor chip 200 and the first lower redistribution pad 140 to each other. For example, the chip connection terminal 230 may conduct a power supply or a data signal between the lower semiconductor chip 200 and the first lower redistribution pad 140.

The chip connection terminal 230 may have a first surface in direct contact with the chip pad 220 of the lower semiconductor chip 200, and a second surface in direct contact with the first pad capping pattern 147 of the first lower redistribution pad 140.

The chip connection terminal 230 may be, for example, at least one of a solder ball, a pillar, or a bump. However, a type of the chip connection terminal 230 is not limited thereto, and may be changed in various ways.

The chip connection terminal 230 may include a conductive material. For example, the chip connection terminal 230 may include any one of a metal such as tin (Sn), silver (Ag), zinc (Zn), or a lead (Pb), or an alloy thereof. However, the conductive material included in the chip connection terminal 230 is not limited thereto, and may be changed.

The chip connection terminal 230 may be omitted. For example, the chip pad 220 of the lower semiconductor chip 200 may be disposed directly on the first lower redistribution pad 140.

The lower semiconductor chip 200 may receive at least one of a control signal, a power signal, or a ground signal. The lower semiconductor chip 200 may receive at least one of a control signal, a power signal, or a ground signal for operating the lower semiconductor chip 200 from an external source. The lower semiconductor chip 200 may receive a data signal to be stored in the lower semiconductor chip 200 from the external source, or may provide the external source with data stored in the lower semiconductor chip 200 through the chip connection terminal 230, and one or more of the first and second lower redistribution patterns 120 and 130, first and second lower redistribution pads 140 and 150, and external electrode pad 160 of the lower package substrate 100, or the external connection terminal 190.

The underfill member 240 may be disposed between the lower semiconductor chip 200 and the lower package substrate 100. The underfill member 240 may be disposed in a region between the first surface 100a of the lower package substrate 100 and the lower semiconductor chip 200. For example, the underfill member 240 may fill a gap region remaining after the first lower redistribution pad 140 and the chip connection terminal 230 are formed in the region between the first surface 100a of the lower package substrate 100 and the lower semiconductor chip 200.

The underfill member 240 may be disposed on at least a portion of the first surface 100a of the lower package substrate 100. The underfill member 240 may cover a portion of the first surface 100a of the lower package substrate 100. The underfill member 240 may be disposed on a surface of the lower semiconductor chip 200 that faces the first surface 100a of the lower package substrate 100. The underfill member 240 may be disposed on a side surface of the chip connection terminal 230. The underfill member 240 may be disposed on a side surface of the first lower redistribution pad 140.

The underfill member 240 may extend in the first direction X beyond the lower semiconductor chip 200. An end of the underfill member 240 may protrude outward from side surfaces of the lower semiconductor chip 200. That is, the underfill member 240 may have a portion overlapping the lower semiconductor chip 200 in the third direction Z, which is the vertical direction, and the remaining portion non-overlapping the lower semiconductor chip 200 in the third direction Z.

In some embodiments, the semiconductor package may omit the underfill member 240.

The underfill member 240 may include an insulating material. For example, the underfill member 240 may include an epoxy-based polymer. However, a material included in the underfill member 240 is not limited thereto, and may be changed.

In some embodiments, the underfill member 240 may be a non-conductive film (NCF).

The molding member 250 may be disposed on the first surface 100a of the lower package substrate 100. The molding member 250 may cover at least a portion of the first surface 100a of the lower package substrate 100, the underfill member 240, or the lower semiconductor chip 200. For example, the molding member 250 may completely cover the lower semiconductor chip 200. That is, the molding member 250 may be disposed on side surfaces and an upper surface of the lower semiconductor chip 200, encapsulating the lower semiconductor chip 200.

Accordingly, an upper surface of the molding member 250 may be disposed at a higher level than the upper surface of the lower semiconductor chip 200. However, a placement relationship between the molding member 250 and the lower semiconductor chip 200 is not limited thereto, and may be changed in various ways.

The molding member 250 may include an insulating material. For example, the molding member 250 may include a polymer such as epoxy molding compound (EMC). As another example, the molding member 250 may include an epoxy-based material, a thermoset material, a thermoplastic material, or an ultraviolet (UV)-treated material. However, a material included in the molding member 250 is not limited thereto, and may be changed.

The semiconductor package 10 according to an embodiment may include the plurality of conductive posts 170. The plurality of conductive posts 170 may be disposed on the first surface 100a of the lower package substrate 100.

The plurality of conductive posts 170 may be spaced apart from the lower semiconductor chip 200 in a horizontal direction, such as the in the first direction X and/or the second direction Y. For example, the plurality of conductive posts 170 may be spaced apart from each other while having the lower semiconductor chip 200 therebetween. That is, the plurality of conductive posts 170 may be disposed outside the lower semiconductor chip 200.

The conductive post 170 may be disposed in the molding member 250. The conductive post 170 may be surrounded by the molding member 250. That is, a side surface of the conductive post 170 may be in direct contact with the molding member 250, and surrounded by the molding member 250. However, a placement relationship between the conductive post 170 and the molding member 250 is not limited thereto. For example, another layer may be disposed between the conductive post 170 and the molding member 250.

The conductive post 170 may have a post or a pillar shape in which the conductive post 170 passes through the molding member 250 and extends in the third direction Z, which is the vertical direction. For example, the conductive post 170 may have a cylindrical shape or a square pillar shape. However, a shape of the conductive post 170 is not limited thereto, and may be changed in various ways.

The conductive post 170 may be disposed on the second lower redistribution pad 150. That is, the conductive post 170 may be electrically connected to the second lower redistribution pad 150.

The conductive post 170 may be electrically connected to the lower semiconductor chip 200 through at least some of the first and second lower redistribution patterns 120 and 130 connected to the second lower redistribution pad 150. The conductive post 170 may be electrically connected to the external connection terminal 190 through at least some of the first and second lower redistribution patterns 120 and 130 and the external electrode pad 160.

In detail, the conductive post 170 may include a first part 171 disposed in the pad hole 150H of the second lower redistribution pad 150 and a second part 173 disposed on an upper surface 150_T of the second lower redistribution pad 150.

The first and second parts 171 and 173 of the conductive post 170 may be integrated with each other, and have no boundary surface therebetween. The first and second parts 171 and 173 of the conductive post 170 may be formed together by substantially the same process.

The first part 171 of the conductive post 170 may be disposed in the pad hole 150H of the second lower redistribution pad 150. The first part 171 of the conductive post 170 may be disposed in the pad hole 150H, and may extend in the third direction Z, which is the vertical direction. For example, a sidewall of the first part 171 may be extend in the third direction Z, which is the vertical direction. The sidewall of the first part 171 may be disposed on a sidewall of the pad hole 150H.

The first part 171 of the conductive post 170 may be in direct contact with the second lower redistribution pad 150. Side surfaces 171_S of the first part 171 of the conductive post 170 may be in direct contact with the second pad conductive pattern 155 and the second pad capping pattern 157, which may form an inner surface of the pad hole 150H. A lower surface of the first part 171 may be in direct contact with the upper surface 156_T of the second pad seed pattern 156 that is exposed through the pad hole 150H.

The first part 171 of the conductive post 170 may be surrounded by the second lower redistribution pad 150. However, a placement relationship between the first part 171 of the conductive post 170 and the second lower redistribution pad 150 is not limited thereto, and may be changed in various ways. For example, another layer may be further disposed in at least one of the first part 171 of the conductive post 170 and the second pad conductive pattern 155, between the first part 171 of the conductive post 170 and the second pad seed pattern 156, or between the first part 171 of the conductive post 170 and the second pad capping pattern 157.

The second part 173 of the conductive post 170 may be disposed on the second lower redistribution pad 150. The second part 173 of the conductive post 170 may be connected to the first part 171 disposed above the upper surface 150_T of the second lower redistribution pad 150, and may extend in the third direction Z, which is the vertical direction.

The second part 173 of the conductive post 170 may cover at least a portion of the upper surface 150_T of the second lower redistribution pad 150 and the first part 171 of the conductive post 170 that is disposed in the pad hole 150H. That is, the upper surface 150_T of the second lower redistribution pad 150 may have a portion covered by the molding member 250, and a portion covered by the second part 173 of the conductive post 170.

Side surfaces 173_S of the second part 173 of the conductive post 170 may be in direct contact with the molding member 250. A lower surface of the second part 173 may be in direct contact with the second pad capping pattern 157, which may form the upper surface 150_T of the second lower redistribution pad 150. However, a placement relationship between the second part 173 of the conductive post 170 and the second pad capping pattern 157 of the second lower redistribution pad 150, and a placement relationship between the second part 173 of the conductive post 170 and the molding member 250 are not limited thereto, and may be changed in various ways. For example, another layer may be disposed between the second part 173 of the conductive post 170 and the second pad capping pattern 157 of the second lower redistribution pad 150, and/or between the second part 173 of the conductive post 170 and the molding member 250.

The first part 171 of the conductive post 170 may have a first length h1 in the third direction Z, which is the vertical direction, and the second part 173 may have a second length h2 in the third direction Z. The first length h1 and the second length h2 may be different lengths. For example, the first length h1 may be less than the second length h2.

The first length h1 may indicate the length of the first part 171 of the conductive post 170 in the third direction Z that is disposed in the pad hole 150H of the second lower redistribution pad 150. The first length h1 may be substantially the same as a depth of the pad hole 150H in the third direction Z. That is, a depth or a width of the first length h1 may be as the depth or the width of the pad hole 150H is changed.

In addition, the first length h1 may be substantially the same as a sum of a thickness of the second pad conductive pattern 155 in the third direction Z and a thickness of the second pad capping pattern 157 in the third direction Z. That is, the length of the first part 171 of the conductive post 170 in the third direction Z may be substantially the same as the sum of the thickness of the second pad line pattern 151 of the second pad conductive pattern 155 in the third direction Z, the thickness of the second pad via pattern 153 in the third direction Z, and the thickness of the second pad capping pattern 157 in the third direction Z.

The second length h2 may indicate the length of the second part 173, included in the conductive post 170 and disposed on the upper surface 150_T of the second lower redistribution pad 150, from its lower surface to the upper surface in the third direction Z.

In an embodiment, a ratio of the first length h1 to the second length h2 may be about 1:30 to about 1:60. However, this ratio is an example, and a relationship and a length ratio between the first length h1 and the second length h2 may be changed in various ways.

The ratio of the length of the first part 171 of the conductive post 170 in the third direction Z to the length of the second part 173 in the third direction Z may be within the above-mentioned numerical range. In this case, the conductive post 170 may have improved structural stability by being stably fixed to the pad hole 150H and upper surface 150_T of the second lower redistribution pad 150.

The first part 171 of the conductive post 170 may have a first width W1 in the first direction. The second part 173 may have a second width W2 in the first direction. The second lower redistribution pad 150 may have a third width W3 in the first direction.

Here, the first width W1 may indicate a diameter of the first part 171 of the conductive post 170, the second width W2 may indicate a diameter of the second part 173 of the conductive post 170, and the third width W3 may indicate a width of the upper surface 150_T of the second lower redistribution pad 150. That is, the first width W1 may indicate a distance between opposite side surfaces 171_S of the first part 171 of the conductive post 170, the second width W2 may indicate a distance between opposite side surfaces 173_S of the second part 173 of the conductive post 170, and the third width W3 may indicate a distance between opposite side surfaces 150_S of the second lower redistribution pad 150.

In addition, the first width W1 may be substantially the same as a width of the pad hole 150H of the second lower redistribution pad 150. That is, the first width W1 may be changed as the width of the pad hole 150H is changed in the first direction X.

In an embodiment, the first width W1, the second width W2, and the third width W3 may be different widths. For example, the first width W1 may be smaller than the second width W2 or the third width W3, and the second width W2 may be smaller than the third width W3. That is, the first width W1 may be a relatively small width of the conductive post 170, and the third width W3 may be a relatively large width of the conductive post 170. However, this configuration is an example, and a relationship between the first width W1, the second width W2, and the third width W3 may be changed. For example, in some embodiments, the second width W2 may be larger than the first width W1, and substantially the same as the third width W3.

In an embodiment, a ratio of the first width W1 to the second width W2 may be about 1:2 to about 1:3. However, this ratio is an example, and a ratio of the first width W1 to the second width W2 may be changed.

The ratio of the width of the first part 171 of the conductive post 170 in the first direction X to the width of the second part 173 in the first direction X may be within the above-mentioned numerical range. The first part 171 may be disposed within a portion of the second lower redistribution pad 150, which may improve a bonding strength of the conductive post 170 and the second lower redistribution pad 150. In this case, the conductive post 170 may have improved structural stability against an external force by being stably fixed to the pad hole 150H and upper surface 150_T of the second lower redistribution pad 150.

The first part 171 and second part 173 of the conductive post 170 may have the widths different from each other, which may be a step between the first part 171 and second part 173 of the conductive post 170. That is, the conductive post 170 may have a multi-level structure.

In addition, the first part 171 and second part 173 of the conductive post 170 may have the widths different from each other. Accordingly, the side surface 171_S of the first part 171 of the conductive post 170, the side surface 173_S of the second part 173, and the side surface 150_S of the second lower redistribution pad 150 may be aligned to different boundaries. That is, the side surface 173_S of the second part 173 of the conductive post 170 may protrude further than the side surface 171_S of the first part 171 in the first direction X, and the side surface 150_S of the second lower redistribution pad 150 may protrude further than the side surface 173_S of the second part 173 of the conductive post 170 in the first direction X.

In some embodiments, as described herein, the second width W2 and the third width W3 may be substantially the same as each other. That is, the width of the second part 173 of the conductive post 170 and the width of the upper surface 150_T of the second lower redistribution pad 150 may be substantially the same as each other. In this case, the second part 173 of the conductive post 170 may entirely cover the upper surface 150_T of the second lower redistribution pad 150.

In addition, in a case where the second width W2 and the third width W3 are substantially the same as each other, the side surface 173_S of the second part 173 of the conductive post 170 and the side surface 150_S of the second lower redistribution pad 150 may be aligned on substantially the same boundary. That is, the side surface 173_S of the second part 173 of the conductive post 170 and the side surface 150_S of the second lower redistribution pad 150 may be disposed on substantially the same line and have a continuous boundary extending in the third direction Z.

As shown in FIG. 2, the second lower redistribution pad 150, the pad hole 150H, and the conductive post 170 may each have a circular shape on a plane. However, this shape is an example, and at least one of the second lower redistribution pad 150, the pad hole 150H, and the conductive post 170 may have various polygonal shapes on the plane, such as a square, a pentagon, and a hexagon. For example, the second lower redistribution pad 150 may have a rectangular shape, and the conductive post 170 and the pad hole 150H may have circular shapes.

The first part 171 and second part 173 of the conductive post 170 may include the same conductive material. The first part 171 and second part 173 of the conductive post 170 may include the same conductive material as the second pad conductive pattern 155 of the second lower redistribution pad 150.

In addition, the first part 171 and second part 173 of the conductive post 170 may include the same conductive material as the second pad seed layer 156b of the second pad seed pattern 156. For example, the first part 171 or second part 173 of the conductive post 170 may include copper (Cu). However, this configuration is an example, and the conductive material included in the conductive post 170 may be changed.

The upper package substrate 400 may be disposed on the conductive post 170 and the molding member 250. That is, the upper package substrate 400 may cover an upper surface of the conductive post 170 and the upper surface of the molding member 250.

In an embodiment, the upper package substrate 400 may be the redistribution substrate. However, the upper package substrate 400 is not limited thereto. In some embodiments, the upper package substrate 400 may be the printed circuit board (PCB), the ceramic substrate, the substrate for a wafer level package (WLP), or the substrate for a package level package (PLP). Hereinafter, for purposes of description it may be assummed that the upper package substrate 400 is the redistribution substrate.

The upper package substrate 400 may include an upper redistribution insulation layer 410 and a plurality of upper redistribution patterns 420, 430, and 440.

The upper redistribution insulation layer 410 may include a plurality of upper redistribution insulation layers 411, 413, 415, and 417. The upper redistribution insulation layer 410 may include the first upper redistribution insulation layer 411, the second upper redistribution insulation layer 413, the third upper redistribution insulation layer 415, and the fourth upper redistribution insulation layer 417. The first upper redistribution insulation layer 411, the second upper redistribution insulation layer 413, the third upper redistribution insulation layer 415, and the fourth upper redistribution insulation layer 417 may be sequentially stacked on the conductive post 170 and the molding member 250.

FIG. 1 shows that the upper redistribution insulation layer 410 includes four insulation layers. However, the number of insulation layers included in the upper redistribution insulation layer 410 is not limited thereto, and the number of insulation layers may be varied. For example, the upper redistribution insulation layer 410 may omit one or more of the first to fourth upper redistribution insulation layers 411, 413, 415, and 417, or include another insulation layer in addition to the first to fourth upper redistribution insulation layers 411, 413, 415, and 417.

As another example, the insulation layer included in the upper package substrate 400 may include one insulation layer.

Each of the first to fourth upper redistribution insulation layers 411, 413, 415, and 417 may include the same material as each of the first to the third lower redistribution insulation layers 111, 113, and 115 described herein. For example, each of the first to fourth upper redistribution insulation layers 411, 413, 415, and 417 may include the photo imageable dielectic (a PID) insulating material which may undergo the photoresist process.

The upper package substrate 400 may include the first upper redistribution pattern 420, the second upper redistribution pattern 430, and the third upper redistribution pattern 440. The first upper redistribution pattern 420, the second upper redistribution pattern 430, and the third upper redistribution pattern 440 may be sequentially disposed in the upper redistribution insulation layer 410.

FIG. 2 shows that the upper package substrate 400 includes the plurality of upper redistribution patterns 420, 430, and 440. The the plurality of upper redistribution patterns 420, 430, and 440 may include three upper redistribution patterns. However, the number of upper redistribution patterns included by the upper package substrate 400 is not limited thereto, and the number of upper redistribution patterns may be varied. For example, the upper package substrate 400 may omit one or more of the first to third upper redistribution patterns 420, 430, and 440, or further include another conduction pattern in addition to the first to third upper redistribution patterns 420, 430, and 440.

The first upper redistribution pattern 420 may include a first upper conductive line pattern 421 and a first upper conductive via pattern 423 integrated with each other. The second upper redistribution pattern 430 may include a second upper conductive line pattern 431 and a second upper conductive via pattern 433 integrated with each other. The third upper redistribution pattern 440 may include a third upper conductive line pattern 441 and a third upper conductive via pattern 443 integrated with each other.

Each of the first to third upper redistribution patterns 421, 431, and 441 may be disposed in the first to third upper redistribution insulation layers 411, 413, and 415, respectively. Each of the first to third upper redistribution patterns 421, 431, and 441 may be disposed on at least one of the upper and lower surfaces of each of the first to third upper redistribution insulation layers 411, 413, and 415. For example, the first upper redistribution pattern 421 may be disposed on the upper surface of the first upper redistribution insulation layer 411, the second upper redistribution pattern 431 may be disposed on the upper surface of the second upper redistribution insulation layer 413, and the third upper redistribution pattern 441 may be disposed on the upper surface of the third upper redistribution insulation layer 415.

The first upper conductive via pattern 423 may pass through at least a portion of the first upper redistribution insulation layer 411. The second upper conductive via pattern 433 may pass through at least a portion of the second upper redistribution insulation layer 414. The third upper conductive via pattern 443 may pass through at least a portion of the third upper redistribution insulation layer 415. Each of the first to third upper conductive via patterns 423, 433, and 443 may be connected to at least one of the first to third upper redistribution patterns 421, 431, and 441, or may be connected to the upper surface of the conductive post 170. For example, the first upper conductive via pattern 423 may be disposed between the first upper redistribution patterns 421 and the upper surface of the conductive post 170.

A width of the first upper redistribution pattern 421 in the first direction X may be larger than a width of the first upper conductive via pattern 423 in the first direction X. A width of the second upper redistribution pattern 431 in the first direction X may be larger than a width of the second upper conductive via pattern 433 in the first direction X. A width of the third upper redistribution pattern 441 in the first direction X may be larger than a width of the third upper conductive via pattern 443 in the first direction X.

The first to third upper conductive via patterns 423, 433, and 443 may have each width in the first direction X that is gradually greater further away from the upper surface of the conductive post 170. For example, one or more of the first to third upper conductive via patterns 423, 433, and 443 may be tappered.

The first to third upper redistribution patterns 420, 430, and 440, may include the first to third upper redistribution patterns 421, 431, and 441 and the first to third upper conductive via patterns 423, 433, and 443, respectively. The first to third upper redistribution patterns 420, 430, and 440 may each have the ‘T’ shaped cross section.

The first to third upper redistribution patterns 421, 431, and 441 and the first to third upper conductive via patterns 423, 433, and 443 may have no boundary surface therebetween. For example, the first upper redistribution pattern 421 and the first upper conductive via pattern 423 may be form of the same material at substantially at the same time. However, a relationship between the first to third upper redistribution patterns 421, 431, and 441 and the first to third upper conductive via patterns 423, 433, and 443, and each cross-sectional shape of the first to third upper redistribution patterns 420, 430, and 440 are not limited thereto, and may be changed in various ways. For example, a boundary surface may be disposed between the first upper redistribution pattern 421 and the first upper conductive via pattern 423.

In detail, the first upper redistribution insulation layer 411 may cover a portion of the upper surface of the conductive post 170 and at least a portion of the upper surface of the molding member 250.

The first upper conductive line pattern 421 of the first upper redistribution pattern 420 may be disposed on the upper surface of the first upper redistribution insulation layer 411. An upper surface of the first upper conductive line pattern 421 may be covered by the second upper redistribution insulation layer 413.

The first upper conductive via pattern 423 of the first upper redistribution pattern 420 may extend in the vertical direction by passing through at least a portion of the first upper redistribution insulation layer 411, and may be connected to the first upper conductive line pattern 421 and the conductive post 170.

The first upper conductive via pattern 423 may be disposed in an opening of the first upper redistribution insulation layer 411 that exposes a portion of the upper surface of the conductive post 170.

The second upper redistribution pattern 431 of the second upper redistribution pattern 430 may be disposed on the upper surface of the second upper redistribution insulation layer 413. An upper surface of the second upper conductive line pattern 431 may be covered by the third upper redistribution insulation layer 415.

The second upper conductive via pattern 433 of the second upper redistribution pattern 430 may extend in the vertical direction by passing through at least a portion of the second upper redistribution insulation layer 413, and may be connected to the first upper conductive line pattern 421 and the second upper redistribution pattern 431. The second upper conductive via pattern 433 may be disposed in an opening of the first upper redistribution insulation layer 413 that exposes a portion of the upper surface of the first upper conductive line pattern 421.

The third upper conductive line pattern 441 of the third upper redistribution pattern 440 may be disposed on the upper surface of the third upper redistribution insulation layer 415. A portion of an upper surface of the third upper conductive line pattern 441 may be exposed through an opening 417H included in the fourth upper redistribution insulation layer 417.

The third upper conductive via pattern 443 of the third upper redistribution pattern 440 may extend in the vertical direction by passing through at least a portion of the third upper redistribution insulation layer 415, and may be connected to the second upper redistribution pattern 431 and the third upper conductive line pattern 441. That is, the third upper conductive via pattern 443 may be disposed in an opening of the third upper redistribution insulation layer 415 that exposes a portion of the second upper redistribution pattern 431.

Each of the first to third upper redistribution patterns 420, 430, and 440 may include a conductive material. For example, each of the first to third lower redistribution patterns 420, 430, and 440 may include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof. However, a material included in each of the first to third upper redistribution patterns 420, 430, and 440 is not limited thereto, and may be changed in various ways.

The first to third upper redistribution patterns 420, 430, and 440 may each include first to third upper redistribution seed patterns 425, 435, and 445 respectively disposed between the first to third upper redistribution insulation layers 411, 413, and 415 and the first to third upper redistribution patterns 421, 431, and 441, and between the first to third upper redistribution insulation layers 411, 413, and 415 and the first to third upper conductive via patterns 423, 433, and 443.

The first to third upper redistribution seed patterns 425, 435, and 445 may conformally extend along an inner surface of each opening of the first to third upper redistribution insulation layers 411, 413, and 415. That is, the first to third upper redistribution seed patterns 425, 435, and 445 may conformally extend respectively along lower surfaces of the first to third upper redistribution patterns 421, 431, and 441 and the lower surfaces and side surfaces of the first to third upper conductive via patterns 423, 433, and 443. For example, the first upper redistribution seed pattern 425 may conformally extend respectively along a lower surface of the first upper redistribution pattern 421 and the lower surfaces and side surfaces of the first upper conductive via pattern 423.

Each thickness of the first to third upper redistribution seed patterns 425, 435, and 445 may be smaller than each thickness of the first to third upper redistribution patterns 421, 431, and 441. Each thickness of the first to third upper redistribution seed patterns 425, 435, and 445 may be smaller than each thickness of the first to third upper conductive via patterns 423, 433, and 443.

In an embodiment, each of the first to third upper redistribution seed patterns 425, 435, and 445 may include a multi-layer structure. The first upper redistribution seed pattern 425 may include a first upper redistribution seed layer 425a and a second upper redistribution seed layer 425b, sequentially stacked between the first upper redistribution insulation layer 411 and the first upper redistribution pattern 421. The second upper redistribution seed pattern 435 may include a first upper redistribution seed layer 435a and a second upper redistribution seed layer 435b, sequentially stacked between the second upper redistribution insulation layer 413 and the second upper redistribution pattern 431. The third upper redistribution seed pattern 445 may include a first upper redistribution seed layer 445a and a second upper redistribution seed layer 445b, sequentially stacked between the third upper redistribution insulation layer 415 and the third upper redistribution pattern 441.

The first upper redistribution seed layer 425a may be disposed between the first upper redistribution insulation layer 411 and the second upper redistribution seed layer 425b, and the second upper redistribution seed layer 425b may be disposed between the first upper redistribution pattern 420 and the first upper redistribution seed layer 425a. The first upper redistribution seed layer 435a may be disposed between the second upper redistribution insulation layer 413 and the second upper redistribution seed layer 435b, and the second upper redistribution seed layer 435b may be disposed between the second upper redistribution pattern 430 and the first upper redistribution seed layer 435a. The first upper redistribution seed layer 445a may be disposed between the third upper redistribution insulation layer 415 and the second upper redistribution seed layer 445b, and the second upper redistribution seed layer 445b may be disposed between the third upper redistribution pattern 440 and the first upper redistribution seed layer 445a.

Each of the first to third upper redistribution patterns 425, 435, and 445 may include a conductive material. For example, each of the first to third upper redistribution patterns 425, 435, and 445 may include at least one of copper (Cu), titanium (Ti), titanium tungsten (TiW), titanium nitride (TiN), tantalum (Ta), tantalum nitride (TaN), chromium (Cr), or aluminum (Al), or a combination thereof.

In an embodiment, the first upper redistribution seed layers 425a, 435a, and 445a and the second upper redistribution seed layers 425b, 435b, and 445b may include a material different from each other. For example, each of the first upper redistribution seed layers 425a, 435a, and 445a may include titanium (Ti) or titanium tungsten (TiW), and each of the second upper redistribution seed layers 425b, 435b, and 445b may include copper (Cu). Accordingly, each of the first to third upper redistribution seed patterns 425, 435, and 445 may have the Cu/Ti structure in which copper (Cu) is stacked on titanium (Ti) or the Cu/TiW structure in which copper (Cu) is stacked on titanium tungsten (TiW).

Although not shown in FIG. 1, in some embodiments, an upper semiconductor chip (not shown) may be mounted on the upper package substrate 400. The upper semiconductor chip mounted on the upper package substrate 400 may be a semiconductor chip of a type different from that of the lower semiconductor chip 200 mounted on the lower package substrate 100. For example, the lower semiconductor chip 200 mounted on the lower package substrate 100 may be the logic chip, and the upper semiconductor chip mounted on the upper package substrate 400 may be the memory chip.

As another example, the upper semiconductor chip mounted on the upper package substrate 400 may be a semiconductor chip of the same type as the lower semiconductor chip 200 mounted on the lower package substrate 100.

In some embodiments, the upper semiconductor chip mounted on the upper package substrate 400 may be mounted on the upper package substrate 400 by using the flip chip method. The upper semiconductor chip mounted on the upper package substrate 400 may be connected to at least one upper redistribution pattern of the plurality of upper redistribution patterns 420, 430, and 440. For example, the upper semiconductor chip mounted on the upper package substrate 400 may be electrically connected to the third upper redistribution pattern 440 through a connection terminal such as a solder ball, a pillar, or a bump.

As another example, the upper semiconductor chip mounted on the upper package substrate 400 may be directly connected to the third upper redistribution pattern 440. As another example, the upper semiconductor chip mounted on the upper package substrate 400 may be directly connected to the third upper redistribution pattern 440 by using a wire bonding method.

In addition, although not shown in FIG. 1, in some embodiments, an upper molding member (not shown) may be disposed on the upper package substrate 400. The upper semiconductor chip may be mounted on the upper package substrate 400. In this case, the upper molding member disposed on the upper package substrate 400 may cover at least a portion of the upper semiconductor chip.

A semiconductor package according to a comparative example may be considered for comparison with the semiconductor package 10 according to an embodiment. In the semiconductor package according to the comparative example, a lower redistribution pad connected to the conductive post may not include a conductive pad hole. Accordingly, the conductive post may be in contact with the upper surface of the lower redistribution pad.

In the semiconductor package 10 according to an embodiment, the second lower redistribution pad 150 connected to the conductive post 170 may include the pad hole 150H. Accordingly, the conductive post 170 may have a portion surrounded by the second lower redistribution pad 150 and may be supported and fixed in a horizontal direction, and a remaining portion supported and fixed by the upper surface of the second lower redistribution pad 150 in the vertical direction.

Accordingly, in the semiconductor package 10 according to an embodiment, a contact area between the conductive post 170 and the second lower redistribution pad 150 may be increased compared to the semiconductor package according to the comparative example and a bonding strength between the conductive post 170 and the second lower redistribution pad 150 may be improved, and the conductive post 170 may be inhibited or prevented from being separated from the second lower redistribution pad 150.

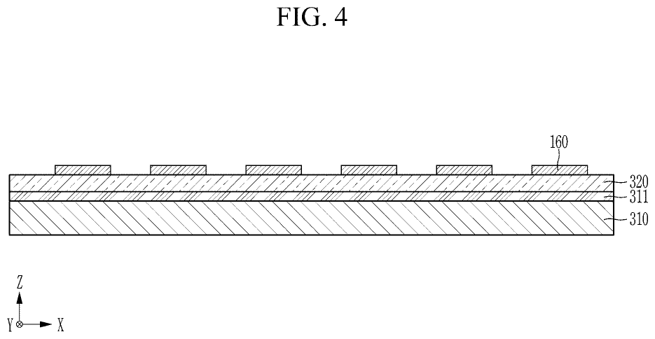

Hereinafter, a method for fabricating a semiconductor device is described with reference to FIGS. 4 through 15. Hereinafter, the same reference numerals refer to the same components described herein, and redundant descriptions thereof may be omitted or simplified, and differences may be mainly described.

FIGS. 4 to 15 are cross-sectional views sequentially showing a method for fabricating a semiconductor package according to an embodiment.

Referring to FIG. 4, a cover layer 320 may be formed on a carrier substrate 310 to which a release film 311 is attached. For example, the release film 311 may be disposed between the cover layer 320 and the carrier substrate 310.

The cover layer 320 may include the same insulating material as the lower redistribution insulation layer 110 (see FIG. 1). However, the cover layer 320 is not limited thereto, and may include an insulating material different from the lower redistribution insulation layer 110. For example, the cover layer 320 may include the organic compound. As another example, the cover layer 320 may include photosensitive polyimide. As another example, the cover layer 320 may include oxide or nitride.

The carrier substrate 310 may include a material stable in a baking process and/or an etching process. The carrier substrate 310 may be a light-transmissive substrate when the carrier substrate 310 may be separated and removed by laser ablation.

Selectively, the carrier substrate 310 may be a heat-resistant substrate when the carrier substrate 310 may be separated and removed by being heating. For example, the carrier substrate 310 may be a glass substrate.

As another example, the carrier substrate 310 may include a heat-resistant organic polymer material such as polyimide, polyether ether ketone (PEEK), poly ether sulfone (PES), or polyphenylene sulfide (PPS). However, a material included in the carrier substrate 310 is not limited thereto, and may be changed.

For example, the release film 311 may be a laser-reactive layer that may enable the carrier substrate 310 to be separated by being vaporized in response to subsequent laser irradiation.

The release film 311 may include a carbon-based material layer. For example, the release film 311 may include a spin-on hardmask (SOH), which is an amorphous carbon layer (ACL) or a film including a hydrocarbon compound or its derivative, having a relatively high carbon content of about 85% to about 99% by weight based on a total weight of carbon content.

The external electrode pad 160 may be formed on the cover layer 320. A step of forming the external electrode pad 160 may include a step of forming and patterning a conductive material layer on the cover layer 320.

A plurality of external electrode pads, including the external electrode pad 160, may be formed on the cover layer 320. The plurality of external electrode pads may be spaced apart in a horizontal direction on an upper surface of the cover layer 320.

The external electrode pad 160 may be formed on the upper surface of the cover layer 320 to have an overall uniform thickness. A lower surface of the external electrode pad 160 that is in contact with the upper surface of the cover layer 320 may be a flat surface.

The external electrode pad 160 may include a metallic material. However, the external electrode pad 160 is not limited thereto, and may have a multi-layer structure in which each layer is made of different metallic materials.

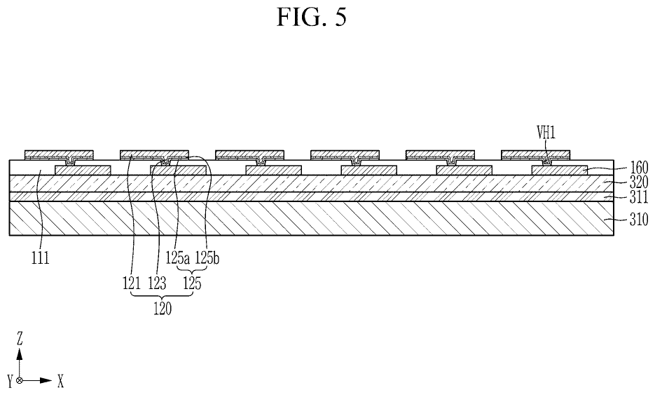

Referring to FIG. 5, the first lower redistribution insulation layer 111 may be formed to include a first opening VH1 exposing a portion of the external electrode pad 160.

A step of forming the first lower redistribution insulation layer 111 may include a step of forming the first opening VH1 by forming an insulating material layer covering the external electrode pad 160 and the cover layer 320, and removing a portion of the insulating material layer. The portion of the insulating material layer may be removed through exposure and development processes. For example, a reactive ion etching (RIE) process, or laser drilling may be performed by using plasma to form the first opening VH1 in the first lower redistribution insulation layer 111.

The first opening VH1 in the first lower redistribution insulation layer 111 may expose the external electrode pad 160, and may have a width gradually smaller in the horizontal direction closer to the external electrode pad 160. Here, the first opening VH1 in the first lower redistribution insulation layer 111 may have a tapered width in the horizontal direction as being closer to the external electrode pad 160.

The first lower redistribution seed pattern 125, the first lower conductive line pattern 121, and the first lower conductive via pattern 123 may be formed on the first lower redistribution insulation layer 111.

In detail, a lower redistribution seed material layer may be formed entirely covering the first lower redistribution insulation layer 111. That is, the lower redistribution seed material layer may be formed on the upper surface of the first lower redistribution insulation layer 111, an inner surface of the first opening VH1, and the upper surface of the external electrode pad 160 that is exposed through the first opening VH1. For example, the lower redistribution seed material layer may be formed by a physical vapor deposition (PVD) process.

The lower redistribution seed material layer formed on the upper surface of the first lower redistribution insulation layer 111 may serve as an electrode for a subsequent electroplating process.

The lower redistribution seed material layer may include a first lower redistribution seed material layer and a second lower redistribution seed material layer, including conductive materials different from each other. For example, the first lower redistribution seed material layer may include titanium (Ti) or titanium tungsten (TiW), and the second lower redistribution seed material layer may include copper (Cu). Accordingly, the lower redistribution seed material layer may have the Cu/Ti structure in which copper (Cu) is stacked on titanium (Ti) or the Cu/TiW structure in which copper (Cu) is stacked on titanium tungsten (TiW). However, this configuration is an example, and the material included in the first lower redistribution seed material layer and/or the second lower redistribution seed material layer may be changed in various ways.

A photoresist pattern may be formed including an opening exposing a portion of the lower redistribution seed material layer. The first conductive line pattern 121 and the first conductive via pattern 123 may be formed by performing an electroplating process of using the lower redistribution seed material layer as a seed. For example, the first conductive line pattern 121 and the first conductive via pattern 123 may be formed at substantially the same time and formed of the same material. For example, there may be no boundary between the first conductive line pattern 121 and the first conductive via pattern 123.

A portion of the exposed lower redistribution seed material layer may be removed by removing the photoresist pattern formed on the lower redistribution seed material layer. For example, portions of the lower redistribution seed material layer that are non-overlapping the first lower conductive line pattern 121 and/or the first lower conductive via pattern 123 may be removed.

A portion of the lower redistribution seed material layer exposed by the first lower conductive line pattern 121 may be removed to form the first lower redistribution seed layer 125a and the second lower redistribution seed layer 125b, which may remain between the upper surface of the first lower redistribution insulation layer 111 and the first lower conductive line pattern 121, between the first lower conductive via pattern 123 and the inner surface of the first opening VH1, and between the first lower conductive via pattern 123 and the external electrode pad 160.

The first lower redistribution seed layer 125a may include the same material as the first lower redistribution seed material layer described herein, and the second lower redistribution seed layer 125b may include the same material as the second lower redistribution seed material layer described herein.

The first lower conductive line pattern 121, the first lower conductive via pattern 123, and the first lower redistribution seed pattern 125 may form the first lower redistribution pattern 120.

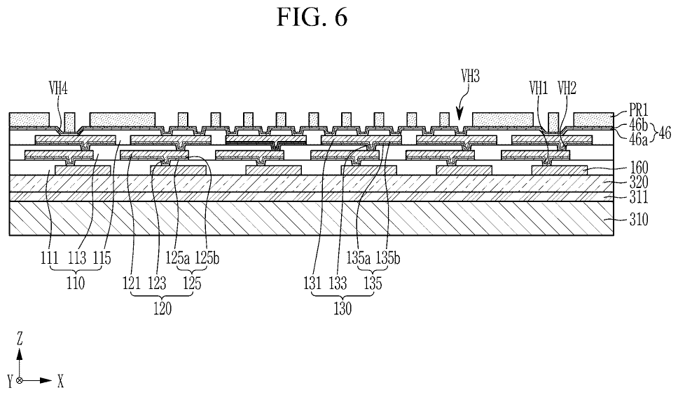

Referring to FIG. 6, the second lower redistribution insulation layer 113 and the second lower redistribution pattern 130, including a second opening VH2, may be formed on the first lower redistribution insulation layer 111 and the first lower redistribution pattern 120 through a process which is substantially the same or similar to the process of forming the first lower redistribution insulation layer 111 and the first lower redistribution pattern 120 described with reference to FIG. 5.

In detail, the second lower redistribution seed pattern 135 including the first lower redistribution seed layer 135a and the second lower redistribution seed layer 135b may be formed to cover the upper surface of the second lower redistribution insulation layer 113, an inner surface of the second opening VH2, and a portion of the upper surface of the first lower conductive line pattern 121 that is exposed through the second opening VH2.

The second lower conductive line pattern 131 may extend along the upper surface of the second lower redistribution insulation layer 113, and the second lower conductive via pattern 133 may be formed to fill the second opening VH2.

The second lower conductive line pattern 131, the second lower conductive via pattern 133, and the second lower redistribution seed pattern 135 may form the second lower redistribution pattern 130.

The third lower redistribution insulation layer 115 including a third opening VH3 and a fourth opening VH4, exposing portions of the upper surface of the second lower conductive line pattern 131, may be formed on the second lower redistribution insulation layer 113 and the second lower redistribution pattern 130.

A pad seed material layer 46 may be formed entirely covering the third lower redistribution insulation layer 115. That is, the pad seed material layer 46 may be formed on the upper surface of the third lower redistribution insulation layer 113, inner surfaces of the third and fourth openings VH3 and VH4, and the upper surface of the second conductive line pattern 131 that is exposed through the third and fourth openings VH3 and VH4. For example, the pad seed material layer 46 may be formed through the physical vapor deposition (PVD) process.

The pad seed material layer 46 formed on the upper surface of the third lower redistribution insulation layer 115 may serve as the electrode for the subsequent electroplating process.

The pad seed material layer 46 may include a first pad seed material layer 46a and a second pad seed material layer 46b, including conductive materials different from each other. For example, the first pad seed material layer 46a may include titanium (Ti) or titanium tungsten (TiW), and the second pad seed material layer 46b may include copper (Cu). Accordingly, the pad seed material layer 46 may have the Cu/Ti structure in which copper (Cu) is stacked on titanium (Ti) or the Cu/TiW structure in which copper (Cu) is stacked on titanium tungsten (TiW). However, this configuration is an example, and the material included in the first pad seed material layer 46a or the second pad seed material layer 46b may be changed in various ways.

A first photoresist pattern PR1 that includes an opening exposing a portion of the pad seed material layer 46 may be formed through an exposure and development processes.

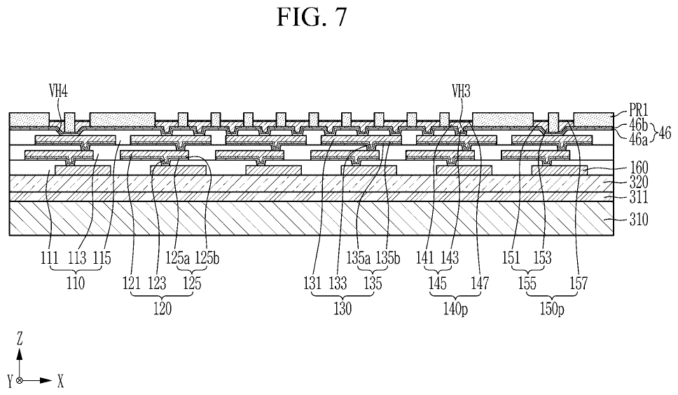

The opening of the first photoresist pattern PR1 may define a region where a first preliminary lower redistribution pad 140p (see FIG. 7) and a second preliminary lower redistribution pad 150p (see FIG. 7), formed through a subsequent process, may be formed.

In detail, the opening of the first photoresist pattern PR1 may expose the pad seed material layer 46 formed on inner surfaces of the third and fourth openings VH3 and VH4 of the third lower redistribution insulation layer 115, and upper surface portions of the third lower redistribution insulation layer 115 disposed adjacent to the third and fourth opening VH3 and VH4.

A portion of the first photoresist pattern PR1 may cover at least a portion of the pad seed material layer 46 formed on the upper surface of the second lower conductive line pattern 131 that is exposed through the fourth opening VH4. That is, a portion of the first photoresist pattern PR1, which may be formed as a pillar in the fourth opening VH4, may overlap the fourth opening VH4. Accordingly, the opening of the first photoresist pattern PR1 may expose a portion of the pad seed material layer 46 formed on the upper surface of the second lower conductive line pattern 131 that is exposed through the fourth opening VH4.

The pad seed material layer 46 formed on the upper surface of the third lower redistribution insulation layer 115 may serve as the electrode for the subsequent electroplating process.

Referring to FIG. 7, the first preliminary lower redistribution pad 140p and the second preliminary lower redistribution pad 150p may be formed in the openings of the first photoresist pattern PR1.

In detail, the first preliminary lower redistribution pad 140p and the second preliminary lower redistribution pad 150p may be formed in the openings of the first photoresist pattern PR1 by performing an electroplating process using the pad seed material layer 46 as the seed.

The first and second pad conductive patterns 145 and 155 having a predetermined height may be formed by a first electroplating process. That is, the first and second pad conductive patterns 145 and 155 may be formed on a surface of the pad seed material layer 46 that is exposed by the opening of the first photoresist pattern PR1 and fill at least a portion of the opening of the first photoresist pattern PR1.

The first and second pad via patterns 143 and 153 of the first and second pad conductive patterns 145 or 155 may respectively fill the third and fourth openings VH3 and VH4 exposed by the first photoresist pattern PR1. The first and second pad line patterns 141 and 151 may cover the upper surface of the third lower redistribution insulation layer 115 and the first and second pad via patterns 143 and 153, adjacent to the third and fourth opening VH3 or VH4.

The first and second pad conductive patterns 145 and 155 may include a conductive material. That is, the first and second pad conductive patterns 145 and 155 may include the same conductive material as the second pad seed material layer 46b of the pad seed material layer 46. For example, the first and second pad conductive patterns 145 and 155 may include copper (Cu). That is, the first and second pad conductive patterns 145 and 155 may be a copper (Cu) plating layer formed by performing electroplating.

The first and second pad capping patterns 147 and 157 may be formed having a predetermined height from the upper surface of the first and second pad conductive patterns 145 and 155 by a second electroplating process. The first and second pad capping patterns 147 and 157 may fill at least a portion of a region remaining after the first and second pad conductive patterns 145 and 155 are formed in the opening of the first photoresist pattern PR1.

The first and second pad capping patterns 147 and 157 may include a conductive material different from that of the first and second pad conductive patterns 145 and 155. For example, the first and second pad capping patterns 147 and 157 may include at least one of nickel (Ni), or gold (Au), or an alloy thereof. That is, the first and second pad capping patterns 147 and 157 may be a nickel (Ni) layer, or a gold (Au) layer, or an alloy plating layer, formed by performing an electroplating.

FIG. 7 shows that the first and second pad capping patterns 147 and 157 are each formed of one layer. However, the structure of the first and second pad capping patterns 147 and 157 is not limited thereto, and at least one of the first or second pad capping pattern 147 or 157 may be formed as a multi-layer structure. For example, at least one of the first or second pad capping pattern 147 or 157 may include a first pad capping layer including nickel (Ni) and a second pad capping layer including gold (Au).

The first pad conductive pattern 145 and the first pad capping pattern 147 may form the first preliminary lower redistribution pad 140p, and the second pad conductive pattern 155 and the second pad capping pattern 157 may form the second preliminary lower redistribution pad 150p.

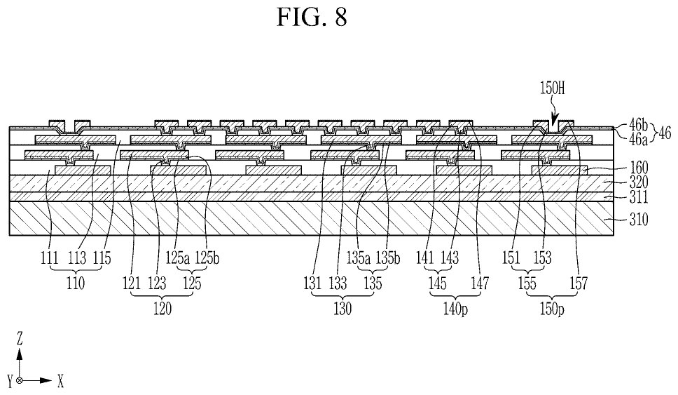

Referring further to FIG. 8 together with FIG. 7, the first photoresist pattern PR1 may be removed. The pad seed material layer 46 may be exposed by removing the first photoresist pattern PR1.

In addition, the pad hole 150H in the second preliminary lower redistribution pad 150p may be formed by removing the first photoresist pattern PR1. That is, the second pad conductive pattern 155 and the second pad capping pattern 157 may not be formed in a region of the pad seed material layer 46 that overlaps the first photoresist pattern PR1 among the regions of the pad seed material layer 46, which are formed on the second conductive line pattern 131 exposed by the fourth opening VH4 of the third lower redistribution insulation layer 115. That is, the pad hole 150H may be formed in a region that overlaps the first photoresist pattern PR1 among the regions of the pad seed material layer 46, which are formed on the second conductive line pattern 131 exposed by the fourth opening VH4.

The pad hole 150H may be formed in a center portion of the second preliminary lower redistribution pad 150p. However, a location of the pad hole 150H is not limited thereto, and may be changed.

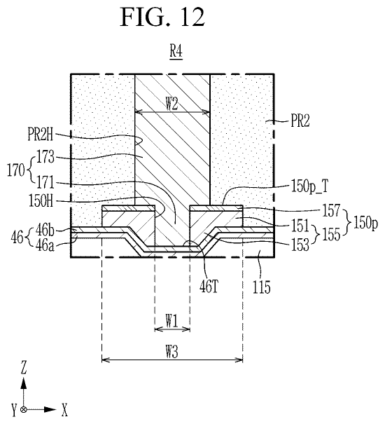

The pad seed material layer 46 exposed through the pad hole 150H of the second preliminary lower redistribution pad 150p may serve as the electrode in the subsequent electroplating process to form the conductive post 170 (see FIG. 12).

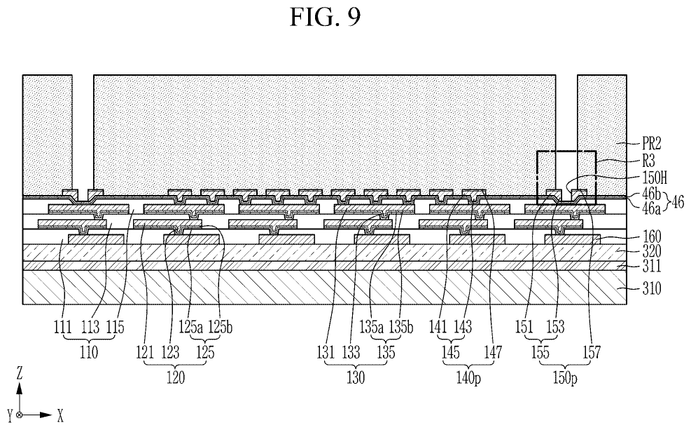

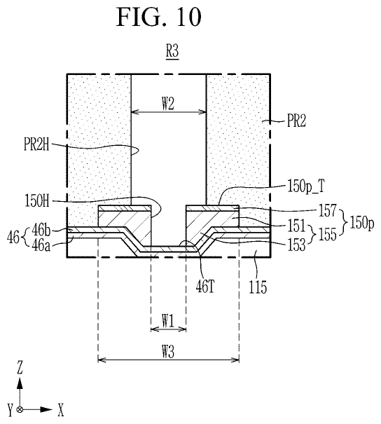

Referring to FIGS. 9 and 10, a second photoresist pattern PR2 may be formed on the first and second preliminary lower redistribution pads 140p and 150p, and the pad seed material layer 46.

A step of forming the second photoresist pattern PR2 may include a step of forming an opening PR2H exposing a portion of the second preliminary lower redistribution pad 150p. The opening PR2H of the second photoresist pattern PR2 may define a region where the conductive post 170 (see FIG. 12) may be formed through the subsequent process.

The opening PR2H of the second photoresist pattern PR2 may expose at least a portion of an upper surface 150p_T of the second preliminary lower redistribution pad 150p. For example, the second photoresist pattern PR2 may cover a partial region of the upper surface 150p_T of the second preliminary lower redistribution pad 150p and expose a remaining region of the upper surface 150p_T.

In addition, the opening PR2H of the second photoresist pattern PR2 may expose the pad hole 150H of the second preliminary lower redistribution pad 150p and the pad seed material layer 46 exposed through the pad hole 150H. That is, a portion of an upper surface 46T of the pad seed material layer 46 may be exposed through the pad hole 150H.

The depth of the pad hole 150H of the second preliminary lower redistribution pad 150p in the third direction Z may be substantially the same as the sum of the thickness of the second pad line pattern 151 of the second pad conductive pattern 155 in the third direction Z, the thickness of the second pad via pattern 153 in the third direction Z, and the thickness of the second pad capping pattern 157 in the third direction Z.

In an embodiment, the pad hole 150H may have the first width W1 in the first direction, the opening PR2H of the second photoresist pattern PR2 may have the second width W2 in the first direction, and the second preliminary lower redistribution pad 150p may have the third width W3 in the first direction.

Here, the first width W1 may indicate a diameter of the pad hole 150H, the second width W2 may indicate a diameter of the opening PR2H of the second photoresist pattern PR2, and the third width W3 may indicate a diameter of the upper surface 150p_T of the second preliminary lower redistribution pad 150p. However, this configuration is an example, and the sizes and shapes of the pad hole 150H, the opening PR2H of the second photoresist pattern PR2, and the upper surface 150p_T of the second preliminary lower redistribution pad 150p may be changed in various ways.

In addition, the first width W1 may be substantially the same as the width of the first part 171 (see FIG. 12) of the conductive post 170 (see FIG. 12) and the second width W2 may be substantially the same as the width of the second part 173 (see FIG. 12) of the conductive post, formed through the subsequent process. That is, the first width W1 of the pad hole 150H and the second width W2 of the opening PR2H of the second photoresist pattern PR2 may be changed. Accordingly, the widths of the first and second parts 171 and 173 of the conductive post 170 may be changed in various ways.

In an embodiment, the first width W1, the second width W2, and the third width W3 may be different from one another. For example, the first width W1 may be smaller than the second width W2 and the third width W3, and the second width W2 may be smaller than the third width W3. That is, the first width W1 may be a relatively small width of the conductive post 170, and the third width W3 may be a relatively large width of the conductive post 170. However, this configuration is an example, and a relationship between the first width W1, the second width W2, and the third width W3 may be changed in various ways. For example, in some embodiments, the second width W2 may be larger than the first width W1, and substantially the same as the third width W3.

In addition, a ratio of the first width W1 to the second width W2 may be about 1:2 to about 1:3. However, this configuration is an example, and a ratio of the first width W1 to the second width W2 may be changed.

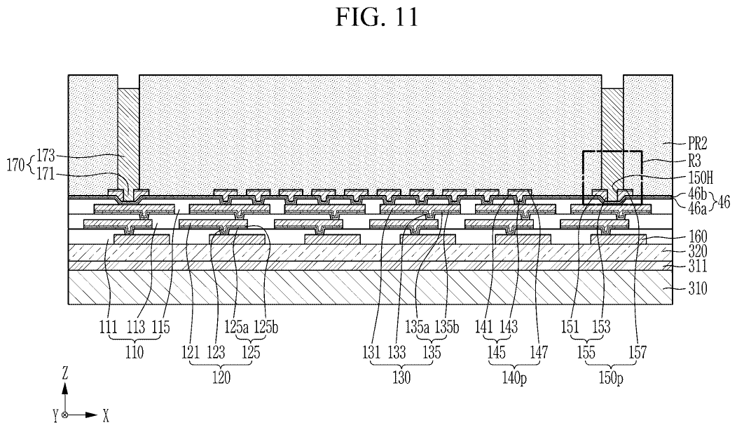

Referring to FIG. 11 and FIG. 12, the conductive post 170 may be formed in the opening PR2H of the second photoresist pattern PR2 and the pad hole 150H by performing an electroplating process using the pad seed material layer 46 exposed through the pad hole 150H as the seed.

In detail, the conductive post 170 having a predetermined height from the upper surface 46T of the pad seed material layer 46 may be formed by performing an electroplating process using the pad seed material layer 46 exposed through the pad hole 150H as the seed.

The conductive post 170 may fill the pad hole 150H. The conductive post 170 may cover the upper surface 150p_T of the second preliminary lower redistribution pad 150p, and fill at least a portion of the opening PR2H of the second photoresist pattern PR2.

Accordingly, the conductive post 170 may include the first part 171 formed in the pad hole 150H, and the second part 173 covering the upper surface 150p_T of the second preliminary lower redistribution pad 150p and formed in the opening PR2H of the second photoresist pattern PR2. That is, the first part 171 and second part 173 of the conductive post 170 may be formed by substantially the same electroplating process, and the first part 171 and the second part 173 may be integrated with each other.

The first part 171 of the conductive post 170 may fill the pad hole 150H. Accordingly, the width of the first part 171 in the first direction X may be substantially the same as the width of the pad hole 150H in the first direction X. That is, the first part 171 of the conductive post 170 can have the first width W1 in the first direction.

In addition, the second part 173 of the conductive post 170 may fill at least a portion of the opening PR2H of the second photoresist pattern PR2. Accordingly, the width of the second part 173 of the conductive post 170 in the first direction may be substantially the same as width of the opening PR2H of the second photoresist pattern PR2 in the first direction. That is, the second part 173 of the conductive post 170 can have the second width W2 in the first direction.

A relationship between the first width W1, the second width W2, and the third width W3, and numerical ranges of the first width W1 and the second width W2 are substantially the same as those described herein with reference to FIG. 11. Therefore, further descriptions thereof may be omitted.

The conductive post 170 may include the same conductive material as the second pad conductive pattern 155 of the second preliminary lower redistribution pad 150p. In addition, the conductive post 170 may include the same conductive material as the second pad seed material layer 46b of the pad seed material layer 46. For example, the conductive post 170 may include copper (Cu). That is, the first part 171 and second part 173 of the conductive post 170 may be the copper (Cu) plating layer formed by substantially the same electroplating process. However, this configuration is an example, and the conductive material included in the conductive post 170 may be changed.

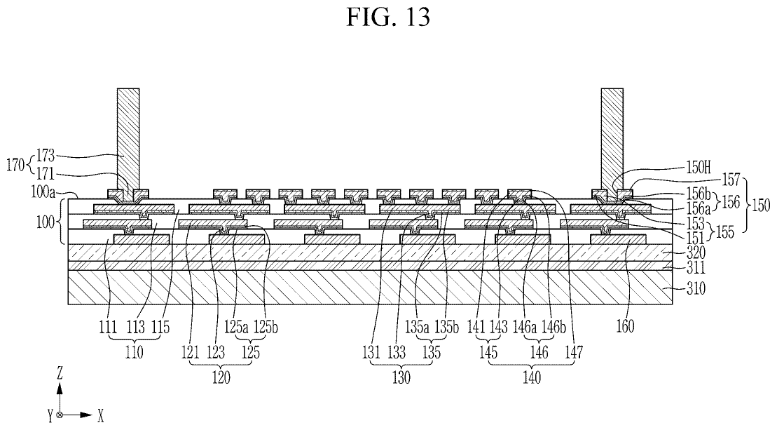

Further referring to FIG. 13 together with FIG. 12, a portion of the pad seed material layer 46 that is exposed may be removed by removing the second photoresist pattern PR2 formed on the pad seed material layer 46. That is, the first and second preliminary lower redistribution pads 140p and 150p and a portion of the pad seed material layer 46 that do not overlap each other may be formed.

A portion of the pad seed material layer 46 may be removed to form the first and second pad seed patterns 146 and 156 including the first pad seed layers 146a and 156a and the first pad seed layers 146b and 156b, remaining between the upper surface of the third lower redistribution insulation layer 115 and the first and second pad line patterns 141 and 151, between the first and second pad via patterns 143 and 153 and the inner surface of the third and fourth openings VH3 and VH4 of the third lower redistribution insulation layer 115, and between the first and second pad via patterns 143 and 153 and the second conductive line pattern 131.

The first pad seed layers 146a and 156a of the first and second pad seed patterns 146 and 156 may include the same material as the first pad seed material layer 46a described herein, and the second pad seed layers 146b and 156b may include the same material as the second pad seed material layer 46b described herein.

The first pad conductive pattern 145, the first pad seed pattern 146, and the first pad capping pattern 147 may form the first lower redistribution pad 140, and the second pad conductive pattern 155, the second pad seed pattern 156, and the second pad capping pattern 157 may form the second lower redistribution pad 150.

The first to third lower redistribution insulation layers 111, 113, and 115 may form the lower redistribution insulation layer 110. The lower redistribution insulation layer 110, the first and second lower redistribution patterns 120 and 130, and the first and the second lower redistribution pads 140 and 150 may form the lower package substrate 100.

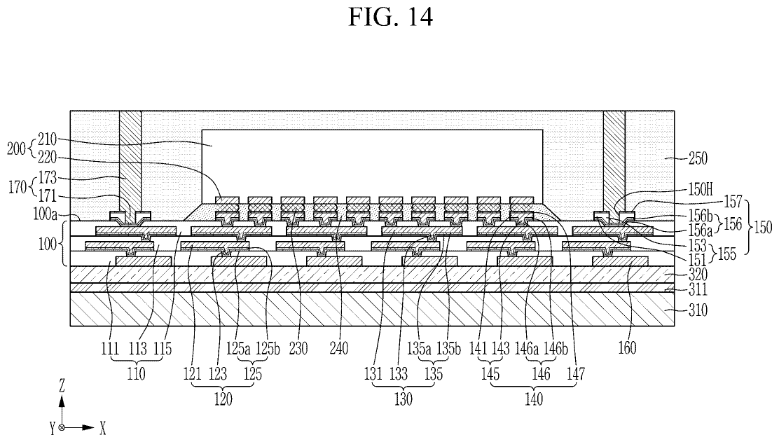

Referring to FIG. 14, the lower semiconductor chip 200 may be attached to the lower package substrate 100, the lower semiconductor chip 200 including the semiconductor substrate 210 and the plurality of chip pads 220 disposed on a surface of the semiconductor substrate 210.

The lower semiconductor chip 200 may be attached to the first surface 100a of the lower package substrate 100 for the chip pad 220 to face the lower package substrate 100. The lower semiconductor chip 200 may be disposed between the conductive posts 170. The lower semiconductor chip 200 may be disposed apart from the conductive posts 170 in a horizontal direction.

A step of attaching the lower semiconductor chip 200 to the lower package substrate 100 may include a step of forming the chip connection terminal 230 between the chip pad 220 of the lower semiconductor chip 200 and the first lower redistribution pad 140.

The chip connection terminal 230 may be, for example, at least one of a solder ball, a pillar, or a bump. However, a type of the chip connection terminal 230 is not limited thereto, and may be changed in various ways.

The chip pad 220 of the lower semiconductor chip 200 may be connected to the first lower redistribution pad 140 through the chip connection terminal 230.

The underfill member 240 disposed in a gap region between the lower semiconductor chip 200 and the lower package substrate 100 may be formed. The underfill member 240 may surround the chip connection terminal 230. For example, the underfill member 240 may be formed by attaching the lower semiconductor chip 200 to the lower package substrate 100 and using a capillary underfill method to fill the gap region between the lower semiconductor chip 200 and the lower package substrate 100.

In some embodiments, the underfill member 240 may be formed by attaching a non-conductive film on the chip pad 220 of the lower semiconductor chip 200, and attaching the lower semiconductor chip 200 to the lower package substrate 100.

The molding member 250 for molding the lower semiconductor chip 200 may be formed after forming the underfill member 240. The molding member 250 may entirely cover the lower semiconductor chip 200 and the conductive post 170. The molding member 250 may cover a side surface and upper surface of the lower semiconductor chip 200, and cover a side surface and upper surface of the conductive post 170.

The molding member 250 may include an insulating material. For example, the molding member 250 may include a polymer such as an epoxy molding compound (EMC).

Steps forming the molding member 250 may include a step of performing a flattening process on the molding member 250 for the upper surface of the conductive post 170 and the upper surface of the molding member 250 to be substantially flat after forming the molding member 250. For example, the flattening process may be performed by chemical mechanical polishing (CMP).

Accordingly, the upper surface of the conductive post 170 and the upper surface of the molding member 250 may be disposed at substantially the same level, and the upper surface of the conductive post 170 and the upper surface of the molding member 250 may each be disposed at a higher level than the upper surface of the lower semiconductor chip 200.

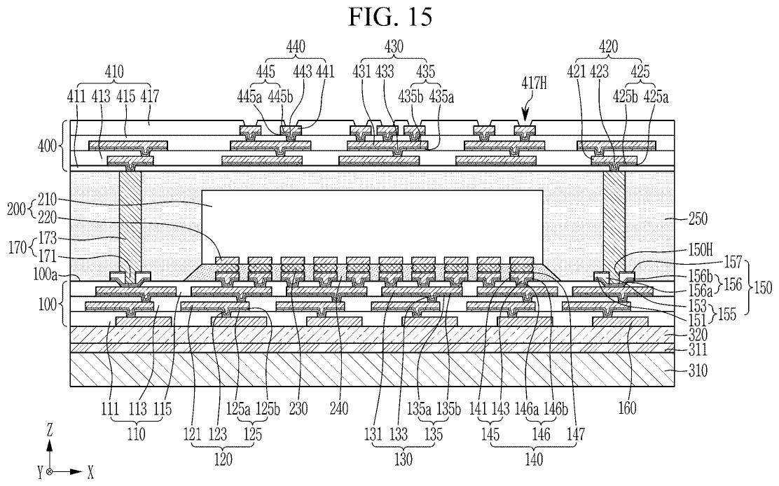

Referring to FIG. 15, the first upper redistribution insulation layer 411 may be formed on the conductive post 170 and the molding member 250. The first upper redistribution insulation layer 411 may cover the upper surface of the molding member 250 and the upper surface of the conductive post 170.

The first upper redistribution insulation layer 411 may include the photo imageable dielectric (PID) insulating material, which may undergo a photoresist process. For example, the first upper redistribution insulation layer 411 may include photosensitive polyimide (PSPI). However, a material included in the first upper redistribution insulation layer 411 is not limited thereto, and may be changed.

A step of forming the first upper redistribution insulation layer 411 may include a step of forming the opening exposing a portion of the upper surface of the conductive post 170 by performing an exposure and a development to remove a portion of the insulating material layer after forming the insulating material layer entirely covering the conductive post 170 and the molding member 250. For example, a reactive ion etching (RIE) process or a laser drilling may be performed by using the plasma to form the opening of the first lower redistribution insulation layer 411.

The first upper conductive line pattern 421, the first lower conductive via pattern 423, and the first upper redistribution seed pattern 425 may be formed on the first upper redistribution insulation layer 411.

In detail, an upper redistribution seed material layer may be formed entirely covering the first upper redistribution insulation layer 411. For example, the upper redistribution seed material layer may be formed by the physical vapor deposition (PVD) process.

The upper redistribution seed material layer formed on the upper surface of the first upper redistribution insulation layer 411 may serve as the electrode for the subsequent electroplating process.

The upper redistribution seed material layer may include a first upper redistribution seed material layer and a second upper redistribution seed material layer, including conductive materials different from each other. For example, the first upper redistribution seed material layer may include titanium (Ti) or titanium tungsten (TiW), and the second upper redistribution seed material layer may include copper (Cu). Accordingly, the upper redistribution seed material layer may have the Cu/Ti structure in which copper (Cu) is stacked on titanium (Ti) or the Cu/TiW structure in which copper (Cu) is stacked on titanium tungsten (TiW). However, this configuration is an example, and the material included in the first upper redistribution seed material layer or the second redistribution seed material layer may be changed in various ways.

A photoresist pattern may be formed including an opening exposing a portion of the upper redistribution seed material layer, and the first conductive line pattern 421 and the first conductive via pattern 423 may be formed by performing an electroplating process using the upper redistribution seed material layer as the seed.

A portion of the exposed upper redistribution seed material layer may be formed by removing the photoresist pattern formed on the upper redistribution seed material layer. That is, portions of the upper redistribution seed material layer, non-overlapping the first lower conductive line pattern 421 or the first lower conductive via pattern 423 may be removed.

A portion of the upper redistribution seed material layer may be removed to form the first upper redistribution seed pattern 425 including the first upper redistribution seed layer 425a and the second upper redistribution seed layer 425b, remaining between the upper surface of the first upper redistribution insulation layer 411 and the first lower conductive line pattern 421, between the first upper conductive via pattern 423 and the inner surface of the opening of the first upper redistribution insulation layer 411, and between the first upper conductive via pattern 423 and the conductive post 170.

The first upper redistribution seed pattern 425 may include the same material as the first upper redistribution seed material layer described herein, and the second upper redistribution seed layer 425b may include the same material as the second upper redistribution seed material layer described herein.

The first upper conductive line pattern 421, the first upper conductive via pattern 423, and the first upper conductive line pattern 425 may form the first upper redistribution pattern 420.

The second upper redistribution insulation layer 413 including the opening exposing a portion of the first upper conductive line pattern 421 and the second upper redistribution pattern 430 on the first upper redistribution insulation layer 411 and the first upper redistribution pattern 420 may be formed by a process substantially the same or similar to a method described herein for forming the first upper redistribution insulation layer 411 and the first upper redistribution pattern 420.

The third upper redistribution insulation layer 415 including the opening exposing a portion of the second upper conductive line pattern 431 and the third upper redistribution pattern 440 on the second upper redistribution insulation layer 415 and the second upper redistribution pattern 430 may be formed by the process substantially the same or similar to a method described herein for forming the first upper redistribution insulation layer 411 and the first upper redistribution pattern 420.

The fourth upper redistribution insulation layer 417, including the opening 417H exposing a portion of the third upper conductive line pattern 441, may be formed on the third upper redistribution insulation layer 415.

The first to fourth upper redistribution insulation layers 411, 413, 415, and 417 may form the upper redistribution insulation layer 410, and the upper redistribution insulation layer 410 and the first to third upper redistribution patterns 420, 430, and 440 may form the upper package substrate 400.

Although not shown in FIG. 15, in some embodiments, a method may further include a step of mounting, on the upper package substrate 400, the upper semiconductor chip (not shown) connected to at least a portion of the upper redistribution patterns 420, 430, and 440, and a step to forming the upper molding member (not shown) covering the upper semiconductor chip mounted on the upper package substrate 400.

Referring further to FIG. 1 together with FIG. 15, the carrier substrate 310, to which the release film 311 is attached, may be removed from the lower package substrate 100. For example, it may be possible to irradiate a laser or apply heat to the release film 311 in order to separate the carrier substrate 310.

The lower surface of the external electrode pad 160 may be exposed by removing the cover layer 320. For example, the cover layer 320 may be removed by an etching process.

The external connection terminal 190 connected to the external electrode pad 160 may be attached to the second surface 100b of the lower package substrate 100. The external connection terminal 190 may be, for example, at least one of a solder ball, a pillar, or a bump. However, the type of the external connection terminal 190 is not limited thereto, and may be changed in various ways.

A method for fabricating the semiconductor package 10 according to an embodiment may omit one or more steps described herein, or may further include a step of performing an additional process other than those described above.

According to a method for fabricating a semiconductor package according to an embodiment, it may be possible to form the pad hole 150H exposing the pad seed material layer 46 in the second lower redistribution pad 150 connected to the conductive post 170, and form the conductive post 170 by performing an electroplating process using the pad seed material layer 46 exposed by the pad hole 150H.

Accordingly, the present disclosure may achieve improved productivity in a method of manufacturing the semiconductor package 10 by omitting a process step of forming a separate seed material layer to form the conductive post 170.

In addition, the present disclosure may omit a step of forming the separate seed material layer to form the conductive post 170, which may reduce the number and thickness of conductive layers stacked between the second lower redistribution pad 150 and the conductive post 170. In this way, it may be possible to inhibit or prevent the conductive post 170 from being separated from the second lower redistribution pad 150, and may improve a reliability of the semiconductor package 10.

Although embodiments of the present disclosure have been described in detail hereinabove, the scope of the present disclosure is not limited thereto, and may include modifications and alterations made by those skilled in the art and using a basic concept of the present disclosure as defined in the claims.

What is claimed is:

1. A semiconductor package comprising:
a lower package substrate including a lower redistribution insulation layer and a lower redistribution pattern;
a semiconductor chip disposed on the lower package substrate;
a molding member disposed on the lower package substrate and covering at least a portion of the semiconductor chip;
a conductive post disposed in the molding member; and
a lower redistribution pad disposed between the conductive post and the lower redistribution pattern,
wherein the lower redistribution pad includes a pad hole extending from an upper surface of the lower redistribution pad toward a lower surface of the lower redistribution pad, and
a portion of the conductive post is disposed in the pad hole.

2. The semiconductor package of claim 1, wherein
the conductive post includes:
a first part disposed in the pad hole of the lower redistribution pad; and
a second part disposed on the first part,
wherein the second part covers at least a portion of the upper surface of the lower redistribution pad.

3. The semiconductor package of claim 2, wherein
a width of the first part of the conductive post and a width of the second part of the conductive post are different from each other, and
the width of the second part of the conductive post is smaller than or substantially the same as a width of the lower redistribution pad.

4. The semiconductor package of claim 3, wherein
a ratio of the width of the first part of the conductive post to the width of the second part of the conductive post is about 1:2 to about 1:3.

5. The semiconductor package of claim 2, wherein the first part includes a sidewall disposed on a sidewall of pad hole and extending in a vertical direction.

6. The semiconductor package of claim 2, wherein
a height of the first part of the conductive post is different from a height of the second part of the conductive post, and
a ratio of the height of the first part of the conductive post to the height of the second part of the conductive post is about 1:30 to about 1:60.

7. The semiconductor package of claim 2, wherein
the lower redistribution pad includes:
a pad conductive pattern and a pad seed pattern disposed between the lower redistribution insulation layer and the pad conductive pattern;
a side surface of the first part of the conductive post is in direct contact with the pad conductive pattern; and
a lower surface of the first part of the conductive post is in direct contact with the pad seed pattern.

8. The semiconductor package of claim 7, wherein
the pad hole of the lower redistribution pad passes through the pad conductive pattern.

9. The semiconductor package of claim 8, wherein
the second part of the conductive post is in direct contact with at least a portion of the upper surface of the lower redistribution pad.

10. The semiconductor package of claim 7, wherein
the lower redistribution pad further includes
a pad capping pattern disposed between the pad conductive pattern and the second part of the conductive post, and
the pad seed pattern includes
a first pad seed layer and a second pad seed layer sequentially stacked between the pad conductive pattern and the lower redistribution insulation layer.

11. The semiconductor package of claim 10, wherein
the pad conductive pattern includes copper (Cu),
the pad capping pattern includes any one of nickel (Ni) or gold (Au), or a combination thereof,
the first pad seed layer includes at least one of titanium (Ti), tantalum (Ta), tantalum nitride (TaN), titanium tungsten (TiW), or titanium nitride (TIN), and
the second pad seed layer includes copper (Cu).

12. The semiconductor package of claim 7, further comprising
an upper package substrate disposed on the molding member and including an upper redistribution insulation layer and an upper redistribution pattern,
wherein the conductive post is connected to the upper redistribution pattern.

13. A semiconductor package comprising:
a lower package substrate including a lower redistribution insulation layer and a lower redistribution pattern;
a semiconductor chip mounted on the lower package substrate;
a connection terminal disposed between the lower package substrate and the semiconductor chip;
a molding member disposed on the lower package substrate and covering at least a portion of the semiconductor chip;
a conductive post disposed in the molding member;
a first lower redistribution pad disposed between the lower redistribution pattern and the connection terminal;
a second lower redistribution pad disposed at substantially the same level as the first lower redistribution pad, between the conductive post and the lower redistribution pattern; and
an upper package substrate disposed on the molding member, and including an upper redistribution insulation layer and an upper redistribution pattern connected to the conductive post,
wherein the second lower redistribution pad includes a pad hole extending from an upper surface of the second lower redistribution pad toward a lower surface of the second lower redistribution pad,
the conductive post includes:
a first part disposed in the pad hole; and
a second part disposed on the first part and covering at least a portion of the upper surface of the second lower redistribution pad, and
a width of the first part and a width of the second part of the conductive post are different from each other.

14. The semiconductor package of claim 13, wherein
the second lower redistribution pad includes:
a pad conductive pattern;
a pad seed pattern disposed between the lower redistribution insulation layer and the pad conductive pattern; and
a pad capping pattern disposed on the pad conductive pattern,
wherein the pad hole passes through the pad conductive pattern,
the first part of the conductive post is in direct contact with the pad conductive pattern, the pad seed pattern, and the pad capping pattern, and
the second part of the conductive post is in direct contact with the pad capping pattern.

15. The semiconductor package of claim 13, wherein the first part includes a sidewall disposed on a sidewall of pad hole and extending in a vertical direction.

16. A method for fabricating a semiconductor package, the method comprising:
forming a lower package substrate including a lower redistribution insulation layer and a lower redistribution pattern;
forming a pad seed material layer on the lower package substrate;
forming a preliminary lower redistribution pad disposed on the pad seed material layer, and including a pad hole exposing the pad seed material layer;
forming a conductive post on the pad seed material layer exposed through the pad hole and on at least a portion of the preliminary lower redistribution pad;
forming a lower redistribution pad by removing a portion of the pad seed material layer;
mounting a semiconductor chip on the lower package substrate and spaced apart from the conductive post; and
forming a molding member covering the conductive post and the semiconductor chip.

17. The method of claim 16, wherein
forming the preliminary lower redistribution pad includes:
forming a first photoresist pattern, including an opening exposing the pad seed material layer, on the pad seed material layer;
forming the preliminary lower redistribution pad in the opening of the first photoresist pattern by performing a plating process using the pad seed material layer as a seed; and
forming the pad hole by removing the first photoresist pattern.

18. The method of claim 17, wherein
forming the preliminary lower redistribution pad in the opening of the first photoresist pattern includes:
forming a pad conductive pattern, including copper (Cu), on the pad seed material layer; and
forming a pad capping pattern, including any one of nickel (Ni) or gold (Au), or a combination thereof, on the pad conductive pattern,
wherein the pad seed material layer includes a first pad seed material layer and a second pad seed material layer stacked sequentially,
the first pad seed material layer includes at least one of titanium (Ti), tantalum (Ta), tantalum nitride (TaN), titanium tungsten (TiW), or titanium nitride (TiN), and
the second pad seed material layer includes copper (Cu).

19. The method of claim 18, wherein
forming the conductive post includes:
forming a second photoresist pattern including an opening exposing the pad hole and at least a portion of an upper surface of the preliminary lower redistribution pad; and
forming the conductive post in the pad hole and the opening of the second photoresist pattern by performing the plating process using the pad seed material layer as the seed,
wherein forming the lower redistribution pad includes
forming a pad seed pattern by removing a portion of the pad seed material layer, and
the lower redistribution pad includes the pad seed pattern, the pad conductive pattern, and the pad capping pattern.

20. The method of claim 19, further comprising
forming, on the molding member, an upper package substrate including an upper redistribution insulation layer, and an upper redistribution pattern connected to the conductive post.
